(19) United States
(12) Patent Application Publication
(10) Pub. No.: US 2024/0415008 A1
(43) Pub. Date: Dec. 12, 2024

(54) Photovoltaic Devices and Methods for Producing Devices Using Perovskite Materials

(71) Applicants: Alliance for Sustainable Energy, LLC, Golden, CO (US); First Solar, Inc., Tempe, AZ (US)

(72) Inventors: Joseph Jonathan BERRY, Boulder, CO (US); Robert TIRAWAT, Aurora, CO (US); Amy E. LOUKS, Golden, CO (US); Kai ZHU, Littleton, CO (US); Axel Finn PALMSTROM, Golden, CO (US); Qi JIANG, Lakewood, CO (US); Kelly Robert SCHUTT, Wheat Ridge, CO (US); Mengjin YANG, Ningbo (CN); Zhibo ZHAO, Novi, MI (US); Severin Niklas HABISREUTINGER, Oxfordshire (GB)

(21) Appl. No.: 18/399,028

(22) Filed: Dec. 28, 2023

Related U.S. Application Data
(60) Provisional application No. 63/477,630, filed on Dec. 29, 2022.

(51) Int. Cl. H10K 85/50; H10K 30/40; H10K 30/50; H10K 71/12

(52) U.S. Cl. CPC H10K 85/50; H10K 30/40; H10K 30/50; H10K 71/12

(57) ABSTRACT

Methods of making photovoltaic devices and photovoltaic devices including perovskite materials and having contact layers are described herein.

### CROSS-REFERENCE TO RELATED APPLICATIONS

This application claims priority from U.S. Provisional Patent Application No. 63/477,630 filed on Dec. 29, 2022, the contents of which are incorporated herein by reference in the entirety.

### STATEMENT REGARDING FEDERALLY SPONSORED RESEARCH

This invention was made with government support under Contract No. DE-AC36-08GO28308 awarded by the Department of Energy, and under a Cooperative Research and Development Agreement, CRADA #CRD-13-507, between First Solar, Inc. and The National Renewable Energy Laboratory, operated for the United States Department of Energy. The United States Government has rights in this disclosure under Contract No. DE-AC36-08GO28308 between the United States Department of Energy and the Alliance for Sustainable Energy, LLC, the Manager and Operator of the National Renewable Energy Laboratory (NREL). The government has certain rights in the invention.

### BACKGROUND

A problem facing perovskites is instability at elevated temperatures. Currently, the most relevant technology is a perovskite composition high (16% or higher) bromine containing cesium, formamidinum, and methylammonium. However, high bromine compositions lack the stability requirements to meet current operational needs for full-scale implementation in the field, especially when operated at high temperatures. Thus, there remains a need for better temperature-stable perovskite compositions and methods for making them.

### BRIEF DESCRIPTION OF DRAWINGS

The patent or application file contains at least one drawing executed in color. Copies of this patent or patent application publication with color drawing(s) will be provided by the Office upon request and payment of the necessary fee. Example embodiments are illustrated in referenced figures of the drawings. It is intended that the embodiments and figures disclosed herein are to be considered illustrative rather than limiting.

FIG. 1 illustrates a perovskite in a corner-sharing, cubic phase arrangement, according to some embodiments of the present disclosure.

FIG. 2A illustrates three possible corner-sharing phases for perovskites, Panel A) cubic phase (i.e., α-ABX₃), Panel B) a tetragonal crystalline phase (i.e., β-ABX₃), and Panel C) an orthorhombic crystalline phase (i.e., γ-ABX₃), according to some embodiments of the present disclosure.

FIG. 2B illustrates a perovskite in one of the three possible phases, the cubic phase (i.e., α-phase), compared to two non-perovskite phases (i.e., non-corner sharing), according to some embodiments of the present disclosure.

FIG. 3 illustrates 2D, 1D, and 0D perovskite-like structures, in Panels A), B), and C), respectively, according to some embodiments of the present disclosure.

FIG. 4 illustrates a perovskite-containing device, according to some embodiments of the present disclosure.

FIG. 5 illustrates data characterizing a perovskite composition having a relatively high concentration of bromine, about 16 mol % (composition referred to herein as “TC16Br”). Panel (a) illustrates a normalized power conversion efficiency (PCE) of TC16Br during aging at 55° C. Panel (b) illustrates a typical corroded cell after aging due to phase segregation, a photograph of a whole cell (left) and picture of the device as viewed under microscope (right). Panel (c) illustrates the 2D TOF SIMS data of the TC16Br device, and Panel (d) the 3D TOF-SIMS, as measured through the contacts, showing islands of ions formed after migration.

FIG. 6 illustrates PCE box plots for individual additives showing the median and first/third quartile efficiency distribution of the averaged forward/reverse J-V sweep efficiency. Pre-aging PCEs are shown in blue, and post-aging (7 days, 70° C., illuminated) are shown in orange. Dotted lines represent the median performance of the TC8Br control architecture.

FIG. 7 illustrates forward and reverse scans for a device containing the BMIM:BF₄ showing the hysteretic nature. Forward values were 15.1% PCE, a J_{sc} of 22.7 mA cm⁻², a V_{oc} of 1.02 V, and a FF of 65.2% and reverse values were 18.4% PCE, a J_{sc} of 22.8 mA cm⁻², a V_{oc} of 1.05 V, and a FF of 76.8%. When a stabilized power output (SPO) measurement was taken, it stabilized at a PCE of 17.0%, which is approximately the average of the forward and reverse J-V efficiency values (16.8%). Therefore, the averaged median PCE values are used herein.

FIG. 8 illustrates PCE values from solar simulator characterization (average of forward and reverse J-V efficiency) for initial (blue) and post aging (red) of TC8Br devices with various modifications to the TC8Br control device stack, according to some embodiments of the present disclosure. Median PCE (solid) is shown, bound by 1^{st} and 3^{rd} quartiles for each condition. Baseline initial and post-aging performance of control TC8Br is shown with a dotted line for reference.

FIG. 9 illustrates: Panel (a) a diagram of a device stack with a NiOₓ/PTAA bilayer HTL and BMIM:BF₄, according to some embodiments of the present disclosure. Panel (b) illustrates initial (blue) and post-aging (orange) current-voltage measurements obtained for the device stack illustrated in Panel (a). Panel (c) illustrates a normalized PCE over a 7-day test at 70° C. under illumination near maximum power point of NiOₓ/PTAA bi-layer with a TC8Br absorber layer and BMIM:BF₄ additive, also for the device stack illustrated in Panel (a).

FIG. 10 illustrates, Panel (a) a diagram of KS8Br device stack, and Panel (b) a standard “racetrack” contact pattern, according to some embodiments of the present disclosure.

FIG. 11 illustrates absorbance spectrum obtained from a perovskite absorber layer having a low bromine formulation, about 8 mol % bromine (referred to herein as “KS8Br”), according to some embodiments of the present disclosure.

FIG. 12 illustrates a current-voltage (JV) curve for a best-performing KS8Br device, according to some embodiments of the present disclosure.

FIG. 13 illustrates stability performance results obtained from KS8Br devices under 0.77 suns in N₂ at Panel (a) 70° C., and Panel (b) 55° C., according to some embodiments of the present disclosure.

REFERENCE NUMERALS

| | |
|---|---|
| 100 | perovskite |
| 110 | A-cation |
| 120 | B-cation |
| 130 | X-anion |
| 400 | device |
| 410 | substrate |
| 420 | first contact layer |
| 430 | first charge transport layer |
| 440 | perovskite layer |
| 450 | second charge transport layer |
| 460 | second contact layer |

### DETAILED DESCRIPTION

Perovskite-based solar cells are a promising technology for the prospect of providing efficient low cost alternatives to silicon and other solar cells. Selection of material compositions and device architecture are important for better performance and stability of devices using perovskite materials. The material forming a perovskite absorber layer, including halide ratios, additives, and treatments, can be combined with specific device component layers, such as the hole transport layer (HTL) to improve stability and efficiency.

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

Perovskite solar cells operated at a high temperature can sometimes degrade significantly within a week. The amount of bromine present in the devices can be a factor causing the early degradation. In order to increase the stability of perovskite solar cells at a higher temperature, a lower bromine (8%) (referred to herein as “KS8Br”) perovskite and a formamidinium (FA) and cesium containing perovskites have been developed. A specific perovskite formulation tested herein is Cs_{0.05}MA_{0.08}FA_{0.87}Pb(I_{0.92}Br_{0.08})₃. However, other low bromine-containing perovskite formulations may be utilized to obtain similar benefits and are considered within the scope of the present disclosure.

Further improvements to device stability and efficiency may be achieved using a nitrogen quench process. In addition, to further boost efficiency and stability in the KS8Br system, additives in the precursor formulation and a bulk crystallization approach have been shown to be beneficial. Additives evaluated are 1-butyl-3-methylimidazolium tetrafluoroborate (BMIM:BF4), tetradecyl dimethyl (3-sulfopropyl) ammonium hydroxide inner salt (TAH), choline chloride (CC), gallium acetylacetonate (Ga(AcAc)₃), lead(II) thiocyanate (Pb(SCN)₂), oleylamine (OAM), lead(II) chloride (PbCl₂), D-4-tert-butyl-Phe (D4TBP), phenethylammonium iodide (PEAI), and a mixture of 4F-PEAI and Pb(SCN)₂ (FPPS). Other low bromine concentration perovskite formulations, in addition to the KS8Br formulation, may benefit from the use of one or more of these additives.

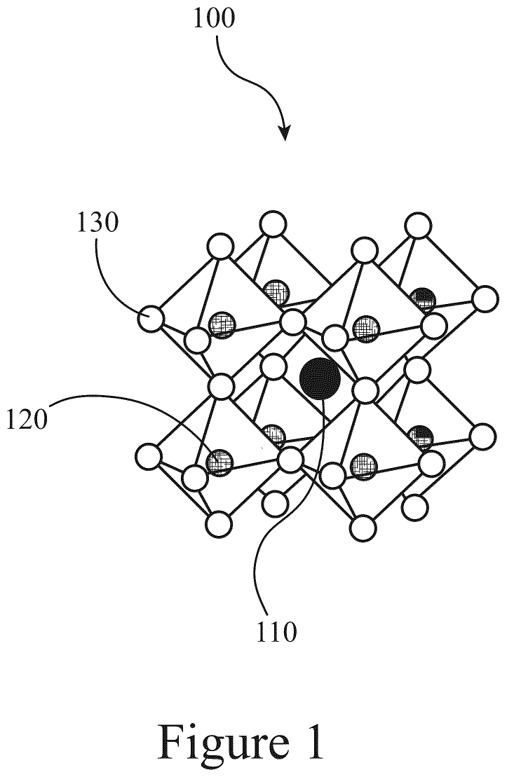

In general, the term “perovskite” refers to compositions having a network of corner-sharing BX₆ octahedra resulting in the general stoichiometry of ABX₃. FIG. 1 illustrates that perovskites 100, for example metal halide perovskites, may organize into a three-dimensional (3D) cubic crystalline structures (i.e., α-phase or α-ABX₃) constructed of a plurality of corner-sharing BX₆ octahedra. In the general stoichiometry for a perovskite, ABX₃, where X (130) is an anion and A (110) and B (120) are cations, typically of different sizes. FIG. 1 illustrates that a perovskite 100 having an α-phase structure may be further characterized by eight BX₆ octahedra surrounding a central A-cation 110, where each octahedra is formed by six X-anions 130 surrounding a central B-cation 120 and each of the octahedra are linked together by “corner-sharing” of anions, X (130).

A perovskite in the α-phase may be visualized as a cubic unit cell, where the B-cation 120 is positioned at the center of the cube, an A-cation 110 is positioned at each corner of the cube, and an X-anion 130 is face-centered on each face of the cube. The X-anions 130 and the B-cations 120 of a perovskite in the α-phase are aligned along an axis; e.g., where the angle at the X-anion 130 between two neighboring B-cations 120 is exactly 180 degrees, referred to herein as the tilt angle. However, a perovskite 100 may assume other corner-sharing crystalline phases having tilt angles not equal to 180 degrees. For example, a perovskite may also assume a tetragonal crystalline phase (i.e., β-ABX₃) and/or an orthorhombic crystalline phase (i.e., γ-ABX₃), where the adjacent octahedra are tilted relative to the reference axes a, b, and c. In addition, the elements used to construct a perovskite, as described above, A-cations 110, B-cations 120, and X-anions 130, may result in 3D non-perovskite structures; i.e., structures where neighboring BX₆ octahedra are not X-anion 130 corner-sharing and/or do not have a unit structure that simplifies to the ABX₃ stoichiometry. One example of a non-perovskite structure is structure characterized by face-sharing BX₆ octahedra resulting in a hexagonal crystalline structure and a second example of a non-perovskite structure is characterized by edge-sharing BX₆ octahedra resulting in an orthorhombic crystalline structure.

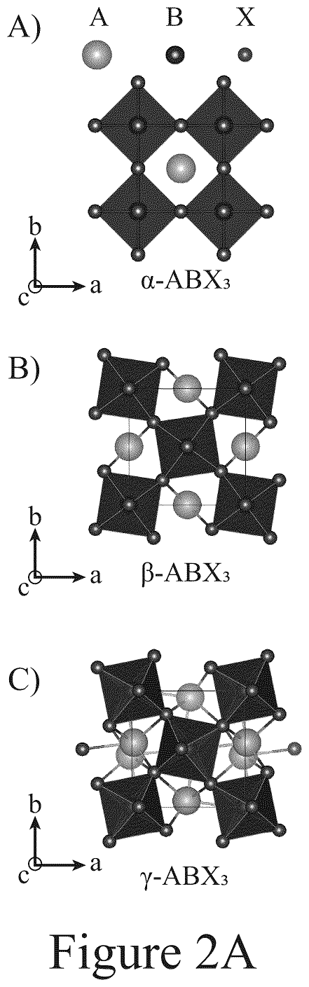

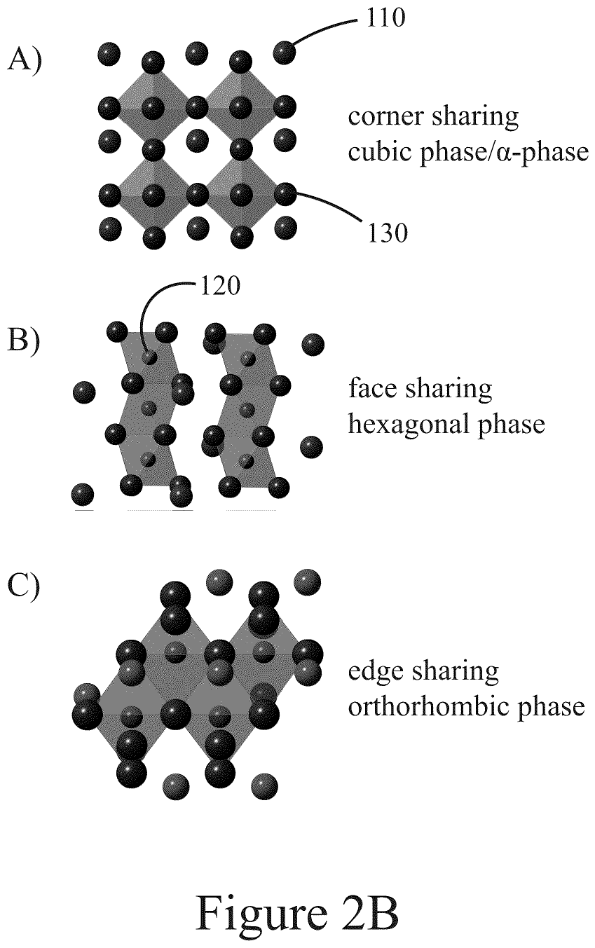

FIG. 2A illustrates that a perovskite can assume other crystalline forms while still maintaining the criteria of an ABX₃ stoichiometry with neighboring BX₆ octahedra maintaining X anion (130) corner-sharing. Thus, in addition to α-ABX₃ perovskites (in the cubic phase) having a tilt angle of 180 degrees, shown in Panel A of FIG. 2A, a perovskite may also assume a tetragonal crystalline phase (i.e., β-ABX₃) (see Panel B of FIG. 2A) and/or an orthorhombic crystalline phase (i.e., γ-ABX₃) (see Panel C of FIG. 2A), where the adjacent octahedra are tilted relative to the reference axes a, b, and c.

FIG. 2B illustrates that the elements used to construct a perovskite, as described above, A-cations 110, B-cations 120, and X-anions 130, may result in 3D non-perovskite structures; i.e., structures where neighboring BX₆ octahedra are not X-anion 130 corner-sharing and/or do not have a unit structure that simplifies to the ABX₃ stoichiometry. Referring to FIG. 2B, Panel A illustrates a perovskite in the cubic phase, i.e., α-ABX₃, compared to a non-perovskite structure constructed of face-sharing BX₆ octahedra resulting in a hexagonal crystalline structure (see Panel B of FIG. 2B) and a non-perovskite structure constructed of edge-sharing BX₆ octahedra resulting in an orthorhombic crystalline structure (see Panel C of FIG. 2B).

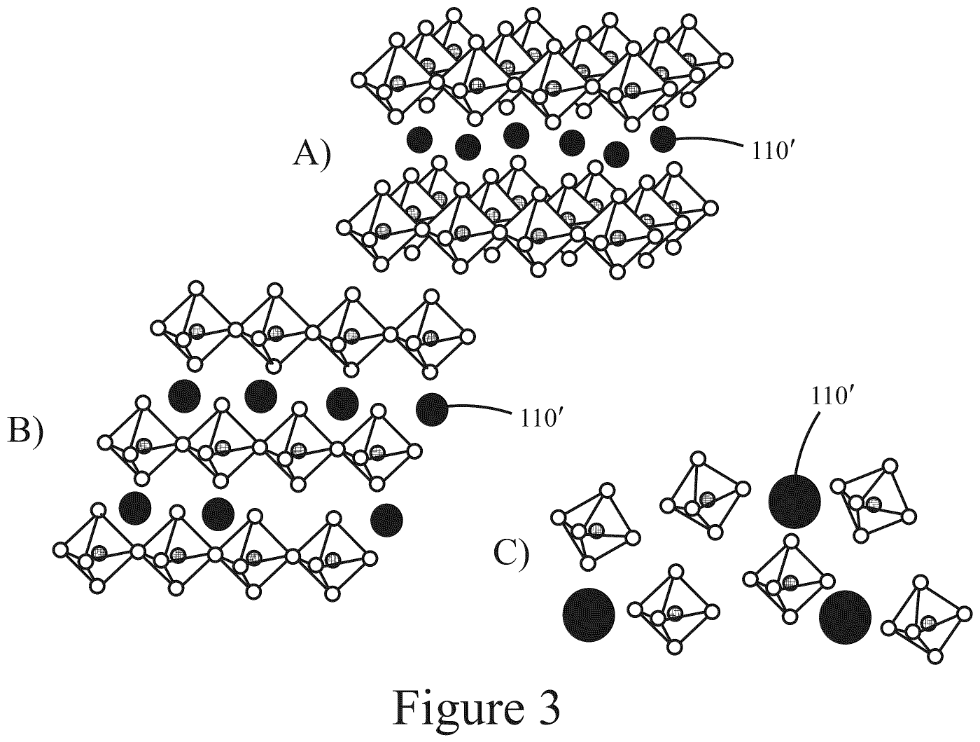

Further, referring now to FIG. 3, the elements used to construct a perovskite, as described above, A-cations 110, B-cations 120, and X-anions 130, may result in non-3D (i.e., lower dimensional structures) perovskite-like structures such as two-dimensional (2D) structures, one-dimensional (1D) structures, and/or zero-dimensional (0D) structures. As shown in FIG. 3, such lower dimensional, perovskite-like structures still include the BX₆ octahedra, and depending on the dimensionality, e.g., 2D or 1D, may still maintain a degree of X-anion corner-sharing. However, as shown in FIG. 3, the X-anion 130 corner-sharing connectivity of neighboring octahedra of such lower dimensional structures, i.e., 2D, 1D, and 0D, is disrupted by intervening A-cations 110. Such a disruption of the neighboring octahedra, can be achieved by, among other things, varying the size of the intervening A-cations 110.

Referring to Panel A of FIG. 3, a 3D perovskite may be transformed to a 2D perovskite-like structure, 1D perovskite-like structure, and/or 0D perovskite-like structure. Where the degree of X-anion 130 corner sharing decreases and the stoichiometry changes according to the formula (A′)ₘ(A)ₙ₋₁BₙX₃ₙ₊₁, where monovalent (m=2) or divalent (m=1) A′ cations 110′ can intercalate between the X-anions of 2D perovskite-like sheets. Referring to Panel B of FIG. 3, 1D perovskite-like structures are constructed by BX₆ octahedral chained segments spatially isolated from each other by surrounding bulky organic A′-cations 110′, leading to bulk assemblies of paralleled octahedral chains. Referring to Panel C of FIG. 3, typically, the 0D perovskite-like structures are constructed of isolated inorganic octahedral clusters and surrounded by small A′-cations 110′, which may be connected via hydrogen bonding. In general, as n approaches infinity the structure is a pure 3D perovskite and when n is equal to 1, the structure is a pure 2D perovskite-like structure. More specifically, when n is greater than 10 the structure is considered to be essentially a 3D perovskite material and when n is between 1 and 5, inclusively, the structure is considered substantially a 2D perovskite-like material.

For simplification, as used herein the term “perovskite” will refer to each of the structures illustrated in FIGS. 1-3, unless specified otherwise. Thus, the term “perovskite” as used herein includes each of true corner-sharing ABX₃ perovskites, face sharing crystal structures, edge sharing crystal structures, as well as perovskite-like compositions having 0D, 1D, and/or 2D structures.

In some embodiments of the present invention, the A-cation 110 may include a nitrogen-containing organic compound such as an alkyl ammonium compound. The B-cation 120 may include a metal and the X-anion 130 may include a halogen. Additional examples for the A-cation 110 include organic cations and/or inorganic cations, for example Cs, Rb, K, Na, Li, and/or Fr. Organic A-cations 110 may be an alkyl ammonium cation, for example a C₁₋₂₀ alkyl ammonium cation, a C₁₋₆ alkyl ammonium cation, a C₂₋₆ alkyl ammonium cation, a C₁₋₅ alkyl ammonium cation, a C₁₋₄ alkyl ammonium cation, a C₁₋₃ alkyl ammonium cation, a C₁₋₂ alkyl ammonium cation, and/or a C₁ alkyl ammonium cation. Further examples of organic A-cations 110 include methylammonium (CH₃NH₃⁺), ethylammonium (CH₃CH₂NH₃⁺), propylammonium (CH₃CH₂CH₂NH₃⁺), butylammonium (CH₃CH₂CH₂CH₂NH₃⁺), formamidinium (NH₂CH═NH₂⁺), hydrazinium, acetylammonium, dimethylammonium, imidazolium, guanidinium, benzylammonium, phenethylammonium, butylammonium and/or any other suitable nitrogen-containing or organic compound. In other examples, an A-cation 110 may include an alkylamine. Thus, an A-cation 110 may include an organic component with one or more amine groups. For example, an A-cation 110 may be an alkyl diamine halide such as formamidinium (CH(NH₂)₂). Thus, the A-cation 110 may include an organic constituent in combination with a nitrogen constituent. In some cases, the organic constituent may be an alkyl group such as straight-chain or branched saturated hydrocarbon group having from 1 to 20 carbon atoms. In some embodiments, an alkyl group may have from 1 to 6 carbon atoms. Examples of alkyl groups include methyl (C₁), ethyl (C₂), n-propyl (C₃), isopropyl (C₃), n-butyl (C₄), tert-butyl (C₄), sec-butyl (C₄), iso-butyl (C₄), n-pentyl (C₅), 3-pentanyl (C₅), amyl (C₅), neopentyl (C₅), 3-methyl-2-butanyl (C₅), tertiary amyl (C₅), and n-hexyl (C₆). Additional examples of alkyl groups include n-heptyl (C₇), n-octyl (C₈) and the like.

Examples of metal B-cations 120 include, for example, lead, tin, germanium, and or any other 2+ valence state metal that can charge-balance the perovskite 100. Further examples include transition metals in the 2+ state such as Mn, Mg, Zn, Cd, and/or lanthanides such as Eu. B-cations may also include elements in the 3+ valence state, as described below, including for example, Bi, La, and/or Y. Examples for X-anions 130 include halogens: e.g., fluorine, chlorine, bromine, iodine and/or astatine. In some cases, the perovskite halide may include more than one X-anion 130, for example pairs of halogens; chlorine and iodine, bromine and iodine, and/or any other suitable pairing of halogens. In other cases, the perovskite 100 may include two or more halogens of fluorine, chlorine, bromine, iodine, and/or astatine.

Thus, the A-cation 110, the B-cation 120, and X-anion 130 may be selected within the general formula of ABX₃ to produce a wide variety of perovskites 100, including, for example, methylammonium lead triiodide (CH₃NH₃PbI₃), and mixed halide perovskites such as CH₃NH₃PbI₃₋ₓClₓ and CH₃NH₃PbI₃₋ₓBrₓ. Thus, a perovskite 100 may have more than one halogen element, where the various halogen elements are present in non-integer quantities; e.g., x is not equal to 1, 2, or 3. In addition, perovskite halides, like other organic-inorganic perovskites, can form three-dimensional (3-D), two-dimensional (2-D), one-dimensional (1-D) or zero-dimensional (0-D) networks, possessing the same unit structure. As described herein, the A-cation 110 of a perovskite 100, may include one or more A-cations, for example, one or more of cesium, FA, MA, etc. Similarly, the B-cation 120 of a perovskite 100, may include one or more B-cations, for example, one or more of lead, tin, germanium, etc. Similarly, the X-anion 130 of a perovskite 100 may include one or more anions, for example, one or more halogens (e.g., at least one of I, Br, Cl, and/or F), thiocyanate, and/or sulfur. Any combination is possible provided that the charges balance.

A photovoltaic device can include a plurality of layers disposed between a light-incident front side and an opposing side or back side. In some embodiments, a device may be bifacial and configured to receive light through both the front side and the opposing side, which may be configured to receive reflected or indirect sunlight. As used herein, the term “layer” refers to a thickness of material provided upon a surface. Each layer can cover all or a portion of the surface. A layer may have sublayers. A layer may have a compositional gradient within the layer across its thickness. In some instances, a transition zone, or region of interdiffusion, may be formed at the junction of adjacent layers. The “thickness” of a layer, as used herein, generally describes a measurement across the layer and substantially perpendicular to a planar surface of the light-incident front side. A central region of a layer thickness can refer to a middle portion of the layer thickness between a front surface of the layer and a back surface of the layer. The central region of a layer thickness may be defined as a middle 70% of the layer thickness. The central region of a layer is bounded on either side by a front region of the layer and a back region of the layer, respectively, with each of the front region and the back region corresponding to 15% of the layer thickness. A composition having an average atomic percent of an element in the layer, provides a value is representative of the entirety of the layer, however an atomic percentage at a particular location within the layer can be graded through the thickness compared to the overall composition of the layer.

Photovoltaic devices can include several material layers deposited sequentially over a substrate. Steps for manufacturing a photovoltaic device may include sequentially disposing functional layers or layer precursors in a “stack” of layers through one or more deposition processes, including, but not limited to, spin coating, spray coating, inkjet printing, slot-die coating, blade coating, dip coating, sputtering, evaporation, molecular beam deposition, pyrolysis, closed space sublimation (CSS), pulsed laser deposition (PLD), chemical vapor deposition (CVD), electrochemical deposition (ECD), atomic layer deposition (ALD), molecular layer deposition, thermal evaporation, flash evaporation, or vapor transport deposition (VTD). Manufacturing of photovoltaic devices can further include the selective removal of portions of certain layers of the stack of layers, such as by scribing, to divide the photovoltaic device into a plurality of photovoltaic cells.

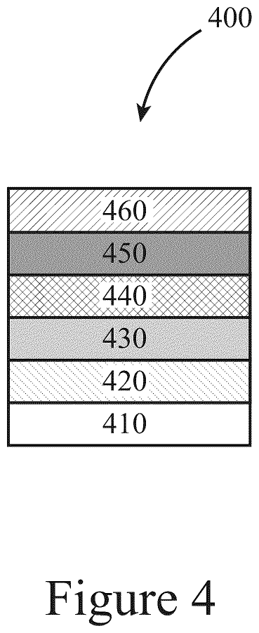

FIG. 4 illustrates a device 400, according to some embodiments of the present disclosure. This exemplary device 400 includes a perovskite layer 440, also referred to as an active layer or an absorber layer, which may have a perovskite composition like any of those described above. For example, a perovskite layer 440 may include a perovskite having a composition of Cs_{(1-x-y)}MAₓFA_{y}Pb(I_{(1-z)}Br_{z})₃, where each of x, y, and z may be between 0 and 1, inclusively. In some embodiments of the present disclosure, the perovskite layer 440 includes a perovskite having a composition of Cs_{(1-x-y)}MAₓFA_{y}Pb(I_{(1-z)}Br_{z})₃, where each of x and y is greater than zero and less than 1, and where z is in a range from 0.01 to 0.15. In some embodiments of the present disclosure, z may be between 0.01 and 0.15, between 0.05 and 0.12, between 0.06 and 0.10, between 0.05 and 0.09, between 0.06 and 0.09, between 0.07 and 0.09, or between 0.06 and 0.08, inclusively. In some embodiments of the present disclosure, x may be between 0.01 and 0.10, between 0.02 and 0.08, or between 0.03 and 0.07, inclusively. In some embodiments of the present disclosure, y may be between 0.80 and 1.0, between 0.82 and 0.92, or between 0.85 and 0.90, inclusively. In some embodiments of the present disclosure, a perovskite layer 440 may have the composition of Cs_{0.08}MA_{0.08}FA_{0.87}Pb(I_{(1-z)}Br_{z})₃. In some embodiments of the present disclosure, a perovskite layer 440 may have the composition of Cs_{0.05}MA_{0.08}FA_{0.87}Pb(I_{0.92}Br_{0.08})₃.

A perovskite layer 440 may further include at least one additive (not shown in FIG. 4). As shown herein, an additive may improve a performance metric of a device 400 having a perovskite layer 440 that includes the additive, when compared to an identical device with a perovskite layer that is additive-free. Additives that may be incorporated into a perovskite layer 440 include 1-butyl-3-methylimidazolium tetrafluoroborate (BMIM:BF₄), 1-butyl-3-methylimidazolium hexafluorophosphate (BMIM:PF₆), lead thiocyanate (Pb(SCN)₂), 4-fluoro-phenylethylammonium iodide (4F-PEAI), excess lead iodide (PbI₂), methylammonium thiocyanate (MASCN), potassium thiocyanate (KSCN), and combinations thereof. The location of an additive in a perovskite layer 440 varies depending on the additive. In some cases, an additive may be positioned primarily at an interface with a neighboring layer; e.g., one or both charge transport layers (430 and/or 450). Other additives may be positioned primarily at the grain boundaries separating individual perovskite grains. Still other additives may be distributed throughout a perovskite layer 440, for example, forming intervening layers of additive positioned between 0D, 1D, 2D, and/or 3D perovskite layers.

Referring again to FIG. 4, a device 400 may include several other layers in order to manufacture an operable device 400, e.g., a photovoltaic device, a light-emitting diode, a display, etc. As illustrated in FIG. 4, a perovskite layer 440 may be positioned between a first charge transport layer (CTL) 430 and a second charge transport layer 450. In some embodiments of the present disclosure, a first CTL 430 may be a hole-transport layer (HTL) and second CTL 450 may be an electron-transport layer (ETL). In some embodiments of the present disclosure, a first CTL 430 may be an ETL and second CTL 450 may be a HTL.

In some embodiments of the present disclosure, an HTL may be constructed of a material that includes a self-assembling monolayer such as at least one of [2-(3,6-dimethoxy-9H-carbazol-9-yl)ethyl]phosphonic acid (MeO-2PACZ), ([4-(3,6-dimethyl-9H-carbazol-9-yl)butyl]phosphonic acid) (Me-4PACZ), (4-(4-(3,6-dimethoxy-9H-carbazol-9yl)butyl)phosphonic acid (MeO-4PACZ), and/or ([2-(9H-carbazol-9-yl)ethyl]phosphonic acid (2PACZ). In some embodiments of the present disclosure, a HTL may include one or more layers constructed of poly[bis(4-phenyl) (2,4,6-trimethylphenyl)amine (PTAA), poly(N,N′-bis-4-butylphenyl-N,N′-bisphenyl)benzidine (Poly-TPD), and nickel oxide. As used herein, nickel oxide (NiOx) refers to a nickel-oxygen compound that may include nickel in mixed oxidation states, which may include NiO, Ni₂O₃, NiO₂, and mixtures thereof. In some embodiments, NiOx has a ratio of oxygen to nickel is in a range of 1:1 to 2:1, inclusive. In some embodiments, NiOx has a ratio of oxygen to nickel is in a range from 1:1 to 1:1.5. In some embodiments, a thickness of the HTL can be between about 2 nm to about 400 nm, such as, for example, between 2 nm to 200 nm, between 2 nm to 100 nm, or between 2 nm to 50 nm. In some embodiments, the HTL comprises two substantially contiguous sublayers.

In some embodiments, the HTL comprises a first sublayer and a second sublayer, where the first sublayer comprises an inorganic hole transport material and the second sublayer comprises an organic hole transport material.

In some embodiments, the first sublayer comprises an inorganic hole transport material and has a thickness in a range of 0.1 nm to 150 nm. In some embodiments, the first sublayer has a thickness in a range of 0.5 nm to 100 nm, 1.0 nm to 100 nm, 4.0 nm to 100 nm, 0.5 nm to 50 nm, 1.5 nm to 50 nm, 2.0 nm to 50 nm, 4.0 nm to 50 nm, 0.5 nm to 25 nm, 1.5 nm to 25 nm, 2.0 nm to 25 nm, 4.0 nm to 25 nm, or 2 nm to 20 nm.

In some embodiments, a second sublayer of the HTL is an organic hole transport material between the perovskite layer and the first sublayer. In some embodiments, the second sublayer of the HTL has a thickness in a range of 0.2 nm to 15 nm. In some embodiments, the second sublayer has a thickness equal to or greater than 0.3 nm, greater than 0.5 nm, or greater than 1.0 nm. In some embodiments, the second sublayer has a thickness equal to or less than 15 nm, less than 10 nm, less than 8.0 nm, less than 5.0 nm, less than 3.0 nm, or less than 2.0 nm.

In some embodiments, the second sublayer comprises at least one hole transport material selected from: PTAA (poly-triarylamine or Poly [bis(4-phenyl)(2,4,6-trimethylphenyl)amine]), P3HT (Poly(3-hexylthiophene-2,5-diyl)), P3HT-COOH (poly[3-(6-carboxyhexyl)thiophene-2,5-diyl]), poly-TPD (4-butyl-N,N-diphenylaniline homopolymer), PEDOT:PSS (Poly(3,4-ethylenedioxythiophene)-poly(styrenesulfonate)), Spiro-OMeTAD (N2,N2,N2′,N2′,N7,N7,N7′,N7′-octakis(4-methoxyphenyl)-9,9′-spirobi[9H-fluorene]-2,2′,7,7′-tetramine), SAF-OMe (N2,N2,N2′,N2′, N7,N7,N7′,N7′-octakis(4-methoxyphenyl)-10-phenyl-1OH-spiro[acridine-9,9′-fluorene]-2,2′,7,7′-tetraamine), OMeTPA-FA, SGT-407, Fused-F, TTF-1 (tetrathiafulvalene), alpha-NPD, TIPS-pentacene (6,13-bis(triisopropyl-silylethynyl)pentacene), PCPDTBT, PCDTBT, or quinolizino acridine. Other suitable organic HTMs may include small molecules that include at least one of a pyrene, thiophene, porphyrin, and/or carbazole; e.g. 1-(N,N-di-p-methoxyphenylamine) pyrene, 4,4′-cyclohexylidenebis[N,N-bis(4-methyl phenyl) benzenamine], 2,5-bis(4,4′-bis(methoxyphenyl) aminophen-4″-yl)-3,4-ethylene dioxythiophene, 2,3,4,5-tetra [4,4′-bis(methoxyphenyl) aminophen-4″-yl]-thiophene, 4,4′,5,5′-tetra [4,4′-bis(methoxyphenyl) aminophen-4″-yl]-2,2′-bithiophene, 5,10,15,20-tetrakis (4-bromophenyl) porphyrin, 5,10,15,20-tetrakis (5-bromopyridine-2-yl) porphyrin, 5,10,15,20-tetrakis (4-bromophenyl) porphyrin zinc(II), 5,10,15,20-tetrakis(5-bromopyridine-2-yl) porphyrin zinc(II), and/or 1,3,6,8-tetra (N, N-p-dimethoxyphenylamino)-9-ethylcarbazole, graphene oxide, copper pthalocyanine, 2,2′,7,7′-Tetra(N,N-di-p-tolyl)amino-9,9-spirobifluorene (spiro-TTB), carbon nanotubes, or EH44 ((9-(2-ethylhexyl)-N,N,N,N-tetrakis(4-methoxyphenyl)-9H-carbazole-2,7-diamine)). In some embodiments the second sublayer of the hole transport layer comprises polyelectrolyte (P3CT-N, P3CT-Rb), spiro[fluorene-9,9′-xanthene] (SFX)-based 3D oligomers (X55). In some embodiments the second sublayer comprises a carbazole-based self-assembled monolayer such as 2PACz, MeO-2PACz, or Me-4PACz.

In some embodiments, the first sublayer comprises at least one oxide. In some embodiments, a hole transport material for the first sublayer may include a nitride compound comprising at least one of: aluminum nitride, molybdenum nitride, nickel nitride, titanium nitride, tungsten nitride, selenium nitride, tantalum nitride, or vanadium nitride. In some embodiments, a hole transport material for the first sublayer is doped with one or more elements selected from Cu, Li, K, Cs, Mg, Ca, Sr, Ba Eu, Tb, or Er. In some embodiments, the first sublayer comprises NiO, CuSCN, CuPc, or CuI. In some embodiments, the first sublayer consists essentially of NiOₓ. In some embodiments, the first sublayer consists essentially of undoped NiOₓ.

In some embodiments, the first sublayer is thicker than the second sublayer. In some embodiments, the first sublayer has a thickness at least two times greater than the second sublayer thickness. In some embodiments, the first sublayer is two to ten times thicker than the second sublayer. In some embodiments, the first sublayer is at least four times thicker than the second sublayer. In some embodiments, the first sublayer is four to twelve times thicker than the second sublayer. In some embodiments, the total thickness of the HTL, including both the first sublayer and the second sublayer, has a total thickness in a range of 1 nm to 200 nm, 1 nm to 100 nm, 5 nm to 80 nm, 5 nm to 70 nm, 5 nm to 50 nm, 10 nm to 100 nm, 10 nm to 80 nm, 10 nm to 50 nm, 4 nm to 30 nm, 4 nm to 25 nm, or 5 nm to 25 nm.

In an example device, the thickness of the perovskite absorber layer 440 can be between about 150 nm to 10000 nm, such as, for example, between 200 nm to 6000 nm in an embodiment, between 300 nm to 3000 nm, between 400 nm to 2000 nm, between 400 nm to 1500 nm, or between 1500 nm to 4000 nm in another example.

In some embodiments of the present disclosure, a HTL may include a layer of NiOₓ and a layer of PTAA, where the PTAA is positioned between the perovskite layer 440 and the NiOx layer. In some embodiments, the HTL may include a layer of NiOₓ and a layer of PTAA, where the PTAA is positioned between the perovskite layer 440 and the NiOₓ layer, and the PTAA is adjacent to and in direct contact with both the perovskite layer 440 and the NiOₓ layer.

The ETL can include one or more layers of material, including, but not limited to, PCBM (phenyl-C61-butyric acid methyl ester), C₆₀, BCP (bathocuproine), lithium fluoride (LiF), or metal oxides, such as TiO₂, ZnO, SnOₓ ZnSnO₄, or SrTiO₃, and the material may include dopants or other additives. In some embodiments, an ETL may be constructed of at least one of: LiF, C₆₀ fullerene, bathocuproine (BCP), or SnO₂.

A device 400 may further include a first contact layer 420 and/or a second contact layer 460. As illustrated in FIG. 4, a first CTL 430 may be positioned between a first contact layer 420 and a perovskite layer 440 and a second CTL 450 may be positioned between a second contact layer 460 and a perovskite layer 440. In some embodiments of the present disclosure, a first contact layer 420 may be constructed of a transparent conducting oxide (TCO) such as indium-doped tin oxide (ITO), fluorine-doped tin oxide, indium zinc oxide, and/or cadmium stannate. In some embodiments of the present disclosure, a second contact layer 460 may be constructed of at least one of gold, silver, molybdenum, copper, carbon, graphene, indium tin oxide (ITO), and/or indium zinc oxide (IZO). In some embodiments of the present disclosure, a device 400 may include a substrate 410 constructed of a glass and/or a polymer.

Referring again to FIG. 4, in some embodiments of the present disclosure, a device 400 may include a perovskite layer 440 having a low-bromine concentration perovskite, e.g., Cs_{(1-x-y)}MAₓFA_{y}Pb(I_{(1-z)}Br_{z})₃, where z is between 0.01 and 0.15, between 0.05 and 0.12, or between 0.06 and 0.10, inclusively, and x and y are as defined above. In this example, the perovskite layer 440 may further include an additive of at least one of 1-butyl-3-methylimidazolium tetrafluoroborate (BMIM:BF₄), 1-butyl-3-methylimidazolium hexafluorophosphate (BMIM:PF₆), lead thiocyanate (Pb(SCN)₂), 4-fluoro-phenylethylammonium iodide (4F-PEAI), excess lead iodide (PbI₂), methylammonium thiocyanate (MASCN), and/or potassium thiocyanate (KSCN). Further, the perovskite layer 440 may be positioned adjacent to and in physical contact with a first CTL 430 constructed of hole-transfer materials, specifically a bilayer HTL constructed of a NiOₓlayer and a PTAA layer, where the PTAA layer is positioned between the NiOₓ layer and the perovskite layer.

Numerous devices, like that illustrated in FIG. 4, were constructed and tested, using varying amounts of bromide in the perovskite composition making up the perovskite layer, using different additives, as well as different HTLs. To facilitate comparison across additives, a baseline fabrication process and testing protocol was selected to target high performing device stacks that could be transferable to scalable deposition methods. Specifically, a modified version of a common anti-solvent quenching method was developed in which the anti-solvent was replaced with high-pressure nitrogen flow during the spin coating step. An automated quench nozzle was used, and flow rates were regulated for process reproducibility. This system simulates an air-knife that may be used in scalable coating processes. A p-i-n device configuration was utilized for each device because of the thermal stability limitations of doped 2,2′,7,7′-Tetrakis(N,N-di-p-methoxyphenylamine)-9,9′-spirobifluorene (Spiro-OMeTAD) that is commonly used as the hole transport layer (HTL) for n-i-p devices. A control device stack of glass/indium doped tin oxide (ITO)/poly[bis(4-phenyl)(2,4,6-trimethylphenyl)amine] (PTAA)/perovskite/C₆₀/bathocuproine (BCP)/silver was chosen for this absorber layer stability study (corresponding to: substrate 410/first contact layer 420/first CTL 430/perovskite layer 440/second CTL 450/second contact layer 460). For testing purposes, the baseline perovskite absorber layer was a triple cation perovskite with Cs_{0.05}MA_{0.16}FA_{0.79}Pb(I_{0.84}Br_{0.16})₃ ink stoichiometry (referred to herein as “TC16Br”), as this structure and composition has a high operational stability at 30° C.

Heat, light, and bias were chosen as accelerated stressors as these are inherent to the operation of a photovoltaic device and cannot be mitigated through packaging. A modified ISOS-L-2 protocol was utilized with a test temperature of 55° C. or 70° C. These temperatures induced a measurable, but not catastrophic, change in power conversion efficiencies (PCEs) within a week of stability testing and allowed for rapid feedback to evaluate the effectiveness of the device strategies being implemented.

Standardized data recording was used across multiple researchers to enable data analytics and identify trends in device performance. Further, a baseline device formulation and device stack were established to use as a control for all the design strategies investigated (i.e., additives, post-treatments, and contact engineering). Implementation of various strategies were evaluated individually and in combination to identify which were complimentary and which were incompatible. Post-aging PCE after 7 days of aging at 70° C. under 0.77 sun illumination (sulfur plasma lamp emission) near maximum power point conditions was the ultimate performance metric used. For each cell, the forward and reverse current-voltage efficiency was averaged to account for potential hysteretic effects. Data statistics are reported as the first quartile, median, and third quartile of the averaged forward and reverse efficiencies for each subset of samples.

Through analysis of the resultant large data set, a high-performing method was identified for fabricating CsMAFA (cesium, methylammonium, formamidinium) p-i-n solar cells with high initial PCE and high stability as demonstrated through 70° C., illuminated aging studies. After averaging, median initial and post-aging PCE values, as well as the spread, were used to evaluate the impact each approach had on the baseline device stack. Three complimentary strategies are identified to increase the performance of triple cation metal-halide perovskite (MHP) p-i-n solar cells: (i) an oxide/polymeric bi-layer HTL with NiOₓ and PTAA, (ii) reduction of bromine content in the absorber layer, and (iii) incorporation of BMIM:BF₄ ionic liquid to the perovskite precursor.

Approach and baseline device stack: Device stability was evaluated in the Stability Parameter Analyzer (SPA) system. The SPA system uses a sulfur plasma lamp to illuminate perovskite solar cells in an enclosed flow cell with an inert nitrogen atmosphere. A closed water loop in the flow cell was used to maintain the nominal operational cell temperature at 55° C. or 70° C. In-situ current-voltage (J-V) sweeps are periodically performed during aging, and the cells are held near maximum power point using a 510-Q load resistor at all other times. To enable a rapid feedback loop for development, devices were typically aged for 168 hours (7 days).

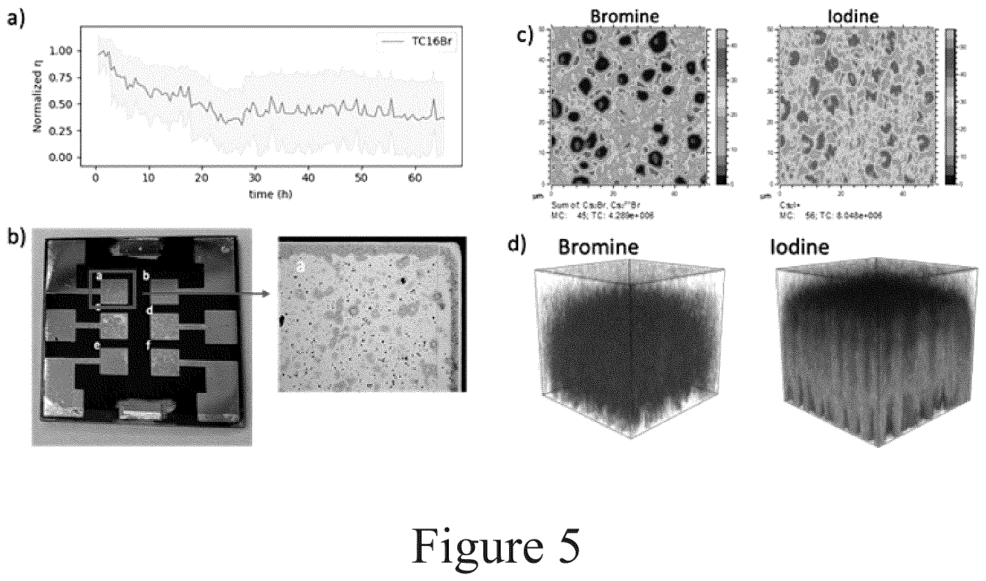

TC16Br devices showed significant degradation at 55° C. in the SPA (see Panel a FIG. 5), dropping below 50% of initial efficiency during the 168-hour test. After samples were removed from aging, corrosion of the metal contacts over the active area could be visually observed, as seen in Panel b of FIG. 5. Time-of-flight secondary ion mass spectrometry (TOF-SIMS) of the corroded contacts was performed to identify the degradation mechanism. Significant halogen species (I, Br) were observed near the degraded regions on the silver, consistent with halogen corrosion of the silver contacts through formation of AgBr and AgI (see Panel c of FIG. 5). Further investigation into the absorber layer using 3-dimensional TOF-SIMS tomography showed significant halogen phase segregation in the bulk of perovskite film. The degradation observed for TC16Br suggests that elevated operating temperatures accelerates halide segregation in MHPs that might otherwise appear phase stable at room temperature testing.

Halide phase segregation instability in a triple cation absorber layer was addressed by reducing the bromine fraction on the X-site by a factor of two, resulting in an ink and final perovskite stoichiometry of Cs_{0.05}MA_{0.08}FA_{0.87}Pb(I_{0.92}Br_{0.08})₃ (referred to herein as “TC8Br”). Modulating the halide content to 8% bromine, a reduction relative to the control, appeared to suppress ion accumulation between the absorber layer and metal contacts in cells aged under illumination at 55° C. in an inert atmosphere. The TC8Br formulation resulted in only a 20% relative loss in median efficiency after aging compared to 55% for the TC16Br formulation. The TC8Br composition was used as the control in the following device stack for subsequent studies: glass/ITO/PTAA/TC8Br/C₆₀/BCP/silver.

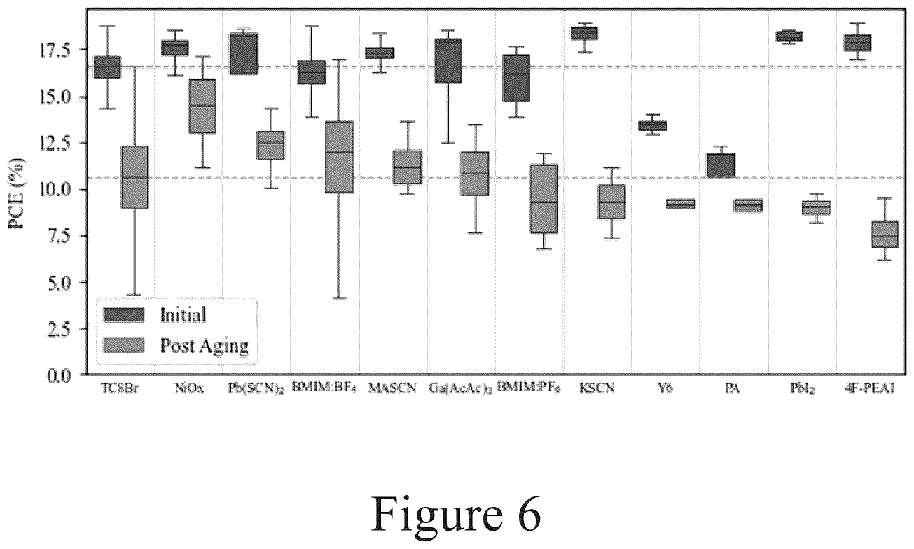

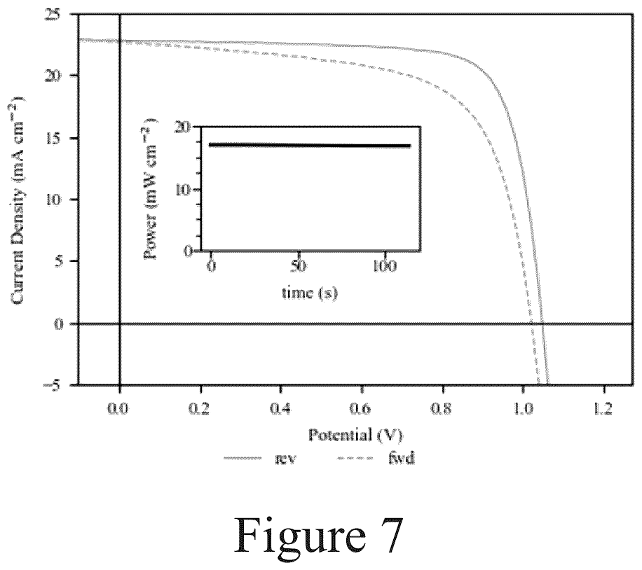

Individual additives to the ink: Additives were incorporated into the precursor solution, also referred to as an ink. The following ink additives were studied: 1-butyl-3-methylimidazolium tetrafluoroborate (BMIM:BF₄), 1-Butyl-3-methylimidazoliumhexafluorophosphate (BMIM:PF₆), lead thiocyanate (Pb(SCN)₂), 4-fluoro-phenylethylammonium iodide (4F-PEAI), excess lead iodide (PbI₂), methylammonium thiocyanate (MASCN), and potassium thiocyanate (KSCN). Initial performance and post-aging performance of all these additives are plotted in FIG. 6. Each additive in this work was targeted for one of three effects: grain growth, passivation, and/or suppression of ion mobility. Several strategies resulted in increased hysteretic current-voltage (J-V) behavior. FIG. 7 shows that for the sweeping conditions used, the average of the forward and reverse J-V measurement is a good approximation for the stabilized power output. For this reason, reported efficiency statistics herein are the average of the forward and reverse J-V efficiency for each cell.

SCN⁻, BF₄⁻, and PF₆⁻ are monovalent pseudohalides with a similar ionic radius to iodide and can incorporate into the perovskite lattice at the X-site. The geometry of these pseudohalides impacts coordination with the central metal cation in the B-X₆ octahedra, consequentially affecting crystallization dynamics and grain growth during perovskite film formation. For thiocyanate-based pseudohalide additives (Pb(SCN)₂, MASCN, and KSCN), initial device efficiency improvements were observed. However, the effect of these additives on post-aging efficiency is more varied. The largest improvement was observed with Pb(SCN)₂, a marginal improvement with MASCN, and a reduction in stability with KSCN. These results suggest that the counter-cation component to the pseudohalide additive can have a significant role in the performance of the absorber.

BF₄⁻ and PF₆⁻ were incorporated as ionic liquid additives with BMIM⁺ cation. For the TC8Br absorber, an increase in initial PCE upon addition of either BMIM:BF₄ or BMIM:PF₆ was not observed. Both ionic liquid additives yielded similar initial median PCE accompanied by an increase in J-V hysteresis. Nevertheless, addition of BMIM:BF₄ increased the median post-aging efficiency of the solar cells by approximately 2.6% absolute PCE over the TC8Br control whereas no stability improvement was observed for BMIM:PF₆.

The addition of larger organic cations to perovskite inks can form 2D or quasi-2D perovskite phases at the perovskite surfaces and grain boundaries, for example, the 4F-PEAI cation. A noticeable improvement to the initial PCE of the TC8Br devices was observed upon addition of 4F-PEAI, increasing in the median initial PCE to 18.2%, compared to 16.8% measured for TC8Br controls. However, the initial performance improvement was not sustained under accelerated stress conditions, resulting in significantly diminished PCEs post-aging.

Post-treatments: Introducing a surface modifier in a post-treatment is a method to alter the perovskite termination and influence the charge and electronic defect density at the perovskite/ETL interface. In p-i-n TC8Br devices, Ga(AcAc)₃ was applied as a post-treatment to the perovskite film prior to the deposition of the fullerene ETL. The Ga(AcAc)₃ post-treatment resulted in an increase in median PCE by over 1% PCE but did not significantly improve device stability. Post-treating the TC8Br absorber with PA had a notably negative effect on the initial PCE.

Contact engineering: Selective contacts not only form interfaces with the MHP absorber, but the underlying growth surface can also affect perovskite crystallization and electronic properties. Differences in material quality arising from substrate-induced growth effects as well as interfacial electrochemical degradation pathways associated with the selective contact layers can significantly impact operational stability of perovskite photovoltaics. Here, two contact engineering strategies are investigated: Y6 at the ETL interface and NiOₓ at the HTL interface.

Y6 is a narrow bandgap non-fullerene acceptor reported to improve photocurrent, moisture tolerance, and operational stability in p-i-n perovskite devices. Y6 in chloroform was applied to TC8Br perovskite by solution processing followed by C₆₀ deposition to form a Y6/C₆₀ ETL. Devices made with Y6 suffered from low short-circuit current density and fill factor relative to the TC8Br control. This may arise from the impact of packing and molecular orientation on charge transport in Y6 films coupled with variation in perovskite termination as a result of process and composition. Stability tests on Y6/C₆₀ ETLs showed a decrease in post-aging performance relative to TC8Br controls.

Some major challenges presented by NiOₓ are the large number of readily formed surface species and the redox reactions that may occur with organic cations in perovskite inks. As a result, low open-circuit voltages are often observed and untreated NiOₓ is not frequently reported in high efficiency devices. Using NiOₓ in place of PTAA in TC8Br devices without any surface treatment of the oxide resulted in a V_{oc} loss of approximately 120 mV. Despite the V_{oc} losses, the NiOₓ devices offered the highest retained efficiencies post-aging, as discussed further below.

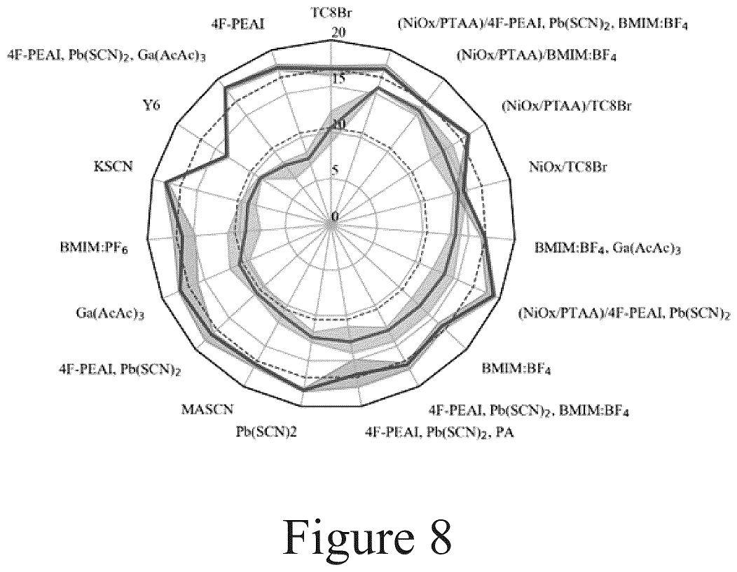

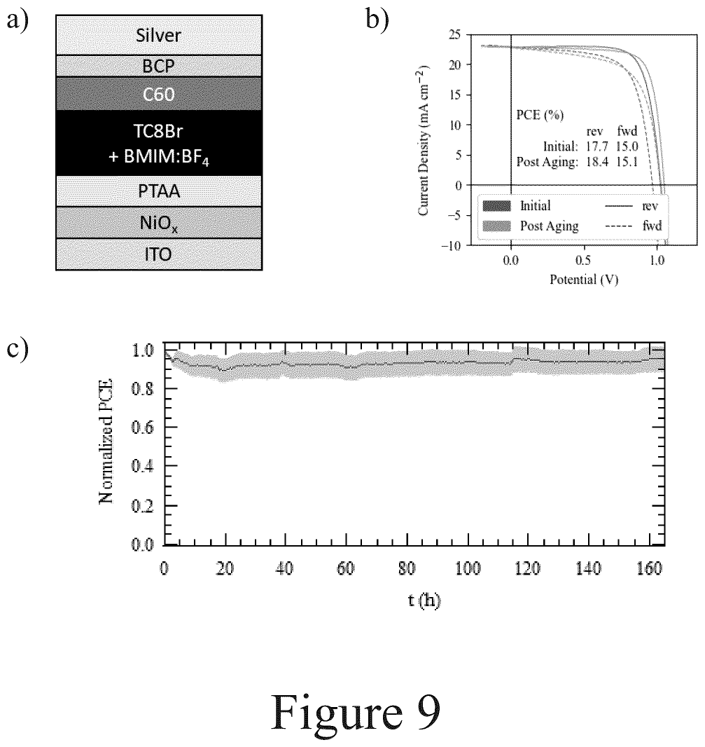

Combined approaches: Initially, each individual additive and post treatment was independently tested with the TC8Br devices. To further advance device performance (i.e., higher PCE and stability), additives and post treatments were explored in combination. Initial and post-aging PCE results from these experiments are summarized in FIG. 8, and device statistics are reported in Table 1. The best-performing device stack resulting from this work is depicted in Panel a of FIG. 9.

The combination of 0.5 mol % 4F-PEAI and 1 mol % Pb(SCN)₂ added directly to the perovskite precursor solution slightly increased the initial median device performance from 17.0% PCE to 17.8% PCE, but did not significantly improve the operational stability at 70° C. When combining 4F-PEAI and Pb(SCN)₂ additives with a Ga(AcAc)₃ post-treatment, initial PCE is improved (18.8%), but post-aging PCE is significantly reduced (8%). This decrease in stability may be the result of two incompatible treatments acting on the perovskite/ETL interface. In contrast, the PA post-treatment decreased the initial efficiency (16.6%) while increasing the post-aging efficiency (13.1%). The effect of PA on post-aging efficiency was less than the incorporation of BMIM:BF₄ with 4F-PEAI and Pb(SCN)₂ (13.2%). Use of the BMIM:BF₄ additive alone resulted in a similar post-aging PCE as that with 4F-PEAI and Pb(SCN)₂. Adding BMIM:BF₄ to the ink and performing the Ga(AcAc)₃ post-treatment increased the post-aging efficiency to 13.4%.

4F-PEAI, PA, and Ga(AcAc)₃ may primarily address recombination at the perovskite/ETL interface while PA and BMIM:BF₄ may modify the bulk perovskite properties in terms of grain structure and defects. FIG. 8 shows that, while combinations of these approaches may show varying degrees of improvement on the initial efficiency, incorporation of NiOₓ at the HTL results in the most significant improvement to the stability. The top four performing device stacks, as defined by the post-degradation efficiency, incorporated NiOₓ or NiOₓ/PTAA HTLs in place of the control PTAA HTL. This includes the NiOₓ/TC8Br condition with no modification to the absorber layer.

TABLE 1
Device Performance Metric Comparison

| | | Initial | | | | Post Aging | | | |
|---|---|---|---|---|---|---|---|---|---|
| | | PCE | J_{SC} | V_{OC} | FF | PCE | J_{SC} | V_{OC} | FF |
| Type | Dir | (%) | (mA cm⁻²) | (V) | (%) | (%) | (mA cm⁻²) | (V) | (%) |
| TC8Br | Fwd | 16.8 | 21.87 | 1.00 | 77.1 | 9.5 | 19.02 | 0.81 | 66.0 |
| | Rev | 17.0 | 21.85 | 1.00 | 77.0 | 11.5 | 19.51 | 0.82 | 71.5 |
| (NiOₓ/PTAA)/BMIM:BF₄ | Fwd | 16.8 | 22.92 | 1.03 | 71.9 | 14.4 | 22.01 | 0.99 | 66.7 |
| | Rev | 18.9 | 23.06 | 1.06 | 77.1 | 16.8 | 22.04 | 1.01 | 75.3 |
| (NiOₓ/PTAA)/ | Fwd | 15.9 | 22.81 | 1.02 | 69.4 | 14.6 | 21.94 | 1.01 | 64.7 |
| 4F-PEAI, Pb(SCN)₂, | Rev | 17.6 | 22.85 | 1.05 | 73.6 | 16.9 | 22.23 | 1.02 | 74.9 |
| BMIM:BF₄ | | | | | | | | | |
| (NiOₓ/PTAA)/TC8Br | Fwd | 17.7 | 22.36 | 1.03 | 76.6 | 14.4 | 20.78 | 0.97 | 72.1 |
| | Rev | 17.8 | 22.35 | 1.03 | 76.3 | 14.6 | 20.79 | 0.98 | 73.9 |
| NiOₓ/TC8Br | Fwd | 14.5 | 21.78 | 0.87 | 77.1 | 14.0 | 20.04 | 0.93 | 77.1 |
| | Rev | 15.0 | 21.85 | 0.87 | 79.4 | 14.5 | 20.19 | 0.94 | 79.3 |
| BMIM:BF₄, Ga(AcAc)₃ | Fwd | 15.7 | 22.44 | 1.03 | 68.0 | 11.2 | 20.91 | 0.97 | 55.5 |
| | Rev | 17.7 | 22.34 | 1.05 | 75.6 | 15.9 | 21.21 | 1.00 | 74.2 |
| (NiOₓ/PTAA)/ | Fwd | 19.2 | 22.84 | 1.07 | 78.5 | 12.8 | 20.52 | 0.98 | 63.6 |
| 4F-PEAI, Pb(SCN)₂ | Rev | 19.3 | 22.99 | 1.09 | 77.7 | 14.1 | 20.73 | 1.00 | 68.8 |
| BMIM:BF₄ | Fwd | 15.1 | 22.51 | 1.00 | 66.1 | 10.6 | 21.19 | 0.90 | 54.3 |
| | Rev | 17.6 | 22.46 | 1.03 | 76.4 | 15.6 | 21.54 | 0.97 | 74.2 |
| 4F-PEAI, Pb(SCN)₂, | Fwd | 16.3 | 22.19 | 1.03 | 72.2 | 10.8 | 20.70 | 0.98 | 52.9 |
| BMIM:BF₄ | Rev | 18.4 | 22.13 | 1.07 | 77.8 | 15.6 | 21.17 | 1.01 | 73.8 |
| 4F-PEAI, Pb(SCN)₂, PA | Fwd | 16.4 | 21.63 | 1.02 | 72.3 | 12.8 | 20.44 | 1.02 | 62.8 |
| | Rev | 16.7 | 21.67 | 1.04 | 72.8 | 13.4 | 20.46 | 1.02 | 66.8 |
| Pb(SCN)₂ | Fwd | 18.2 | 21.93 | 1.02 | 80.3 | 11.8 | 20.42 | 0.86 | 69.9 |
| | Rev | 18.3 | 21.94 | 1.03 | 80.2 | 13.1 | 20.64 | 0.89 | 72.7 |
| MASCN | Fwd | 17.1 | 22.27 | 0.98 | 78.1 | 10.3 | 19.73 | 0.85 | 65.9 |
| | Rev | 17.5 | 22.24 | 0.99 | 78.6 | 12.1 | 20.17 | 0.86 | 73.4 |
| 4F-PEAI, Pb(SCN)₂ | Fwd | 17.6 | 22.04 | 1.05 | 76.5 | 10.5 | 18.23 | 0.96 | 58.8 |
| | Rev | 17.8 | 21.95 | 1.06 | 76.7 | 11.5 | 18.24 | 0.97 | 64.6 |
| Ga(AcAc)₃ | Fwd | 17.8 | 21.91 | 1.02 | 79.7 | 10.4 | 20.02 | 0.79 | 62.4 |
| | Rev | 18.0 | 21.83 | 1.03 | 80.1 | 12.1 | 20.65 | 0.94 | 67.0 |
| BMIM:PF₆ | Fwd | 14.8 | 22.81 | 0.95 | 68.6 | 7.1 | 19.95 | 0.73 | 47.5 |
| | Rev | 17.6 | 22.67 | 0.99 | 79.1 | 11.5 | 21.65 | 0.77 | 68.4 |
| KSCN | Fwd | 18.4 | 22.54 | 1.02 | 80.2 | 9.0 | 17.60 | 0.87 | 60.0 |
| | Rev | 18.6 | 22.53 | 1.03 | 80.5 | 9.7 | 17.65 | 0.88 | 63.0 |
| Y6 | Fwd | 12.2 | 19.80 | 0.97 | 63.9 | 8.3 | 17.69 | 0.79 | 60.1 |
| | Rev | 14.9 | 20.40 | 1.01 | 72.0 | 10.1 | 17.76 | 0.85 | 67.7 |
| 4F-PEAI, Pb(SCN)₂, | Fwd | 18.5 | 22.03 | 1.06 | 79.9 | 8.4 | 17.02 | 1.04 | 47.1 |
| Ga(AcAc)₃ | | | | | | | | | |
| | Rev | 19.0 | 22.10 | 1.08 | 79.7 | 7.7 | 16.17 | 1.04 | 50.9 |
| 4F-PEAI | Fwd | 17.9 | 22.24 | 1.05 | 76.2 | 6.1 | 18.37 | 0.71 | 47.2 |
| | Rev | 18.0 | 22.26 | 1.06 | 75.7 | 9.0 | 19.60 | 0.79 | 59.7 |
| PA | Fwd | 11.3 | 21.35 | 0.91 | 57.2 | 8.4 | 17.07 | 0.75 | 65.7 |
| | Rev | 12.4 | 21.45 | 0.94 | 60.6 | 9.8 | 17.14 | 0.83 | 69.1 |

There is no observed correlation between the initial efficiency and the post-aging efficiency with NiOₓ-containing HTLs. The median initial efficiency of NiOₓ/PTAA HTLs with the 4F-PEAI and Pb(SCN)₂ additive is 19.2%, but this condition shows the lowest stability of the NiOₓ HTL subset. The initial voltage of NiOₓ/PTAA/TC8Br devices are increased by 160 mV over TC8Br on bare NiOₓ. The addition of PTAA in a bilayer structure leads to an improvement of the initial efficiency by approximately 3% compared to the TC8Br, and an improvement in post-aging efficiency of 0.25% (14.25% and 14.5% for NiOₓ/TC8Br and NiOₓ/PTAA/TC8Br conditions, respectively). Surprisingly, the post-aging open-circuit voltage gap between these two devices narrowed to 40 mV as a result of a decrease in V_{oc} of the NiOₓ/PTAA samples and an increase in V_{oc} of the bare NiOₓ samples. Addition of BMIM:BF₄ to the NiOₓ/PTAA HTL, TC8Br samples further increased the median post-aging efficiency to 15.8% with an initial efficiency of 16.8%. Panel b of FIG. 9 shows the pre- and post-aging J-V curves for the champion device with the efficiency curve of NiOₓ/PTAA HTL, TC8Br devices over the course of the 7-day, 70° C. accelerated aging test shown in Panel c of FIG. 9. These samples show a stable or slightly increasing efficiency after an initial bum-in over approximately the first 20 hours. Notably, some devices performed better after the stress test. Adding 4F-PEAI and Pb(SCN)₂ to the NiOₓ/PTAA, BMIM:BF₄ devices increased the initial efficiency while slightly improving the post-aging performance.

The losses across figures of merit are not the same between devices. Devices without either NiOₓ in the HTM or BMIM:BF₄ incorporation show significant loss in short-circuit current density (J_{sc}) post-aging. These J_{sc} losses are significantly suppressed with NiOₓ or BMIM:BF₄ individually but are most stable when these approaches are used together. These results suggest a primary degradation mode arising from the HTL/perovskite interface for p-i-n MHP devices at elevated temperatures under illumination. This instability is likely not a result of direct PTAA/perovskite interactions or a PTAA growth surface, as NiOₓ/PTAA HTL bilayers appear as stable as bare NiOₓHTLs under these test conditions. PTAA may be susceptible to doping and/or a suppressed glass transition temperature in the presence of free halogens. In these tests, NiOₓ appears to maintain carrier selectivity at the HTL/perovskite interface. BMIM:BF₄ improves the performance of PTAA, NiOₓ, and NiOₓ/PTAA devices. The role of BMIM:BF₄ may be two-fold: (i) the BMIM⁺ cation of the BMIM:BF₄ ionic liquid may passivate the HTL/perovskite interface and (ii) the reduction of ionic mobility in the perovskite bulk, suppressing free halogens at device interfaces. However, as BMIM:PF₆ was observed to be less effective than BMIM:BF₄, it is unlikely that HTL passivation with BMIM⁺ is the dominant stabilization mechanism. The reduced ionic mobility reported with BMIM:BF₄ additives is likely a dominant effect.

These studies suggest that BMIM:BF₄ and NiOₓ strategies have the most significant impact on overall device stability, and these approaches are complimentary. Device modifications targeting the perovskite/ETL interface can have positive effects on the initial device efficiency without compromising stability.

### Experimental:

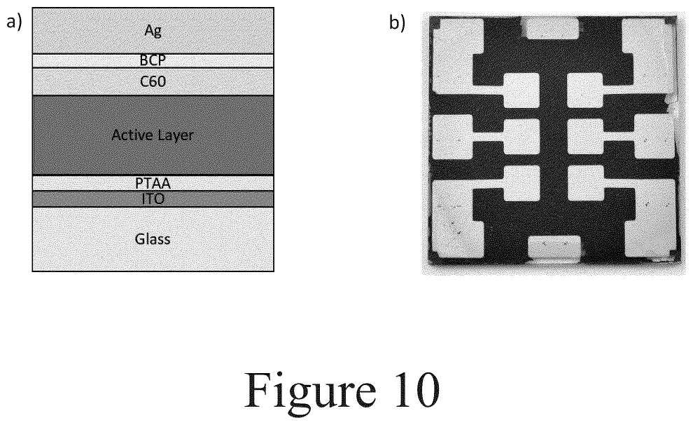

This section describes a process for fabrication of p-i-n-type devices (see Panel a of FIG. 10) with an 8% Br, triple-cation perovskite (KS8Br) active layer and a N₂ quench. This procedure was designed for 25 mm×25 mm ITO substrates. Standard, pre-patterned substrates were sourced from Colorado Concept Coatings (Part No. CCC0068) and are polished soda lime float glass. The substrates were patterned with SiO₂ and <20 Ω/sq. ITO in a center island for the active area and front contacts as well as isolated contact pads along the edges to mitigate poke through issues that may arise during characterization. The standard contact pattern allowed for 6 devices with an active area of 0.122 cm² (see Panel b of FIG. 10).

Perovskite Precursor: Precursor solutions were prepared as follows.
1. Weigh salts into amber vial in Dry Box, ensuring each salt is within ±1% of specification (see Table 2).
2. Seal vial with paraffin and transfer to Solvent Box.
3. Add NMP.
4. Add DMF.
5. Vortex on high (10) until solids are visibly dissolved (˜1 min).
6. Leave on Vortex on low (1) until used.

TABLE 2
Perovskite Absorber Layer Precursor Formulation (1.3M)

| Material | Unit | Qty |
|---|---|---|
| MABr | mg | 11.6 |
| CsI | mg | 16.9 |
| PbBr₂ | mg | 38.2 |
| FAI | mg | 194.5 |
| PbI₂ | mg | 551.4 |
| NMP | μL | 100.0 |
| DMF | μL | 900.0 |

PTAA was prepared as follows:
1. Weigh PTAA into amber vial.
2. Seal vial with paraffin and transfer to Solvent Box.
3. Add Toluene for a 2 mg/mL concentration.
4. Vortex on high (10) until solids are visibly dissolved (˜1 min s).
5. Leave on Vortex on low (1) until used.

Substrates were prepared as follows:
1. Scribe sample ID on glass-side of substrate
2. Prepare Liquinox/DI solution (1:100) bath and DI bath.
3. Sonicate detergent and DI baths for 5 min to degas.
4. Blow substrates with N₂
5. Sonicate in detergent bath, 15 min.
6. Rinse with DI
7. Sonicate in DI bath, 15 min.
8. Remove each substrate from DI and blow off remaining water with N₂.
9. Sonicate in acetone bath, 15 min.
10. Rinse substrates with clean acetone
11. Sonicate in IPA bath, 15 min.
12. Remove each substrate from IPA bath and blow off remaining solvent with N₂.
13. Store substrates in clean container until use.

UV/ozone (UVO) cleaning was completed as follows:
1. Blow off substrates with N₂.
2. UVO substrates for 15 min with dry air. 3. Transfer into spin box.

PTAA deposition was completed as follows and per Table 3.
1. Heat and stabilize hotplate at 100° C. (act.).
2. Blow off substrate with N₂, and place on vacuum chuck.
3. Apply 50 μL PTAA precursor to center of substrate.
4. Start spin.
5. As each substrate is coated, move to preheated hot plate. Anneal at 100° C. for 10 min.

TABLE 3
Specialty Coating Systems G3 spin coater recipe for PTAA

| Step | Ramp (s) | RPM | Dwell (s) | Dispense | Time (s) |
|---|---|---|---|---|---|
| 0 | 0.0 | 0 | 0 | — | 0.1 |
| 1 | 2.0 | 6000 | 30 | — | 0.0 |

Perovskite layer deposition was completed as follows and shown in Table 4. This process used a ⅜″ ID (nom.) stainless steel tube for N₂ delivery. The N₂ pressure was set to approximately 100 psig.
1. Adjust N₂ tube to be approximately 5 mm above sample plane and vertical.
2. Ensure substrates are at room temperature before deposition.
3. Blow off substrate with N₂, and place on vacuum chuck.
4. Apply 50 μL precursor along the front substrate edge.
5. Holding the pipette tip horizontally with forceps, contact the precursor meniscus and drag to the rear of the substrate and back. Make sure to avoid contact with the substrate surface.
6. Move the N₂ tube into position above the center of the substrate and start spin.
7. Once the spin is complete, move the N₂ tube away and move substrate to preheated hot plate.
8. Anneal at 100° C. for 30 min.
9. Remove substrates from hot plate as they complete their anneal.
10. Store substrates in a sealed container, blown out with clean N₂, for transport.

The electron transport and contact layers were deposited immediately following absorber layer deposition. Between absorber layer deposition and evaporation, devices were stored under N₂ and prevent exposure to air.

TABLE 4
Specialty Coating Systems G3 spin coater
recipe for N₂-quenched absorber layer

| Step | Ramp (s) | RPM | Dwell (s) | Dispense | Time (s) |
|---|---|---|---|---|---|
| 0 | 0.0 | 0 | 0 | — | 0.1 |
| 1 | 1.0 | 2000 | 9 | — | 0.0 |
| 2 | 3.0 | 6000 | 1 | — | 0.0 |
| 3 | 0.0 | 6000 | 23 | Solv | 15.0 |

C₆₀, BCP deposition was completed as follows: Blanket coat 25 nm of C₆₀ via thermal evaporation in a baffle boat (RD Mathis SB-6, SB-6B). The first 5 nm was deposited at a slow rate (0.12 Å/s). Afterwards, a faster rate (0.25 to 0.5 Å/s) was used. However, to avoid thermal decomposition, avoided allowing the power to drift significantly above the typical deposition power for a fresh boat with fresh C₆₀. For the W129 Angstrom evaporator, the power was below 17%. Blanket coated 6 nm of BCP via thermal evaporation at 0.15 Å/s using a baffle boat.

Contacts were deposited as follows: Removed substrates from the evaporator. Used a razor to remove the deposited layers from the cathode region. It was best practice to completely remove material from where the metal contact was to be deposited. Masked the substrates and finished them with the desired contact metal. Baseline devices were typically finished with 100 nm of Ag deposited at rates of 0.5 Å/s and 2.0 Å/s for the initial 10 nm and remainder, respectively.

### Results

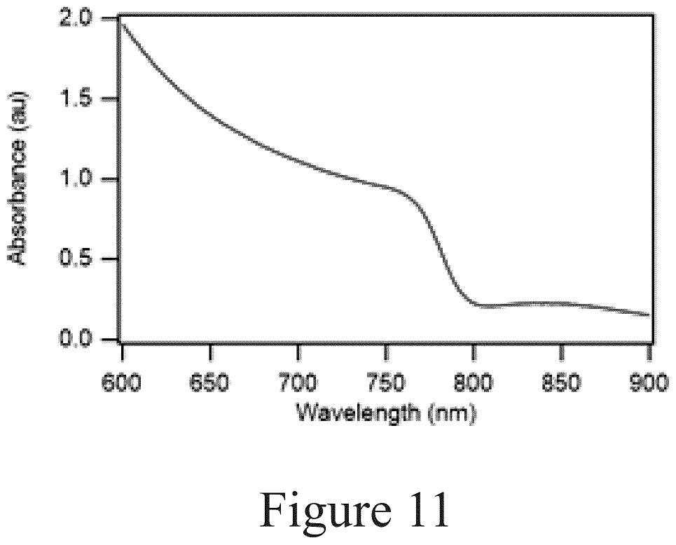

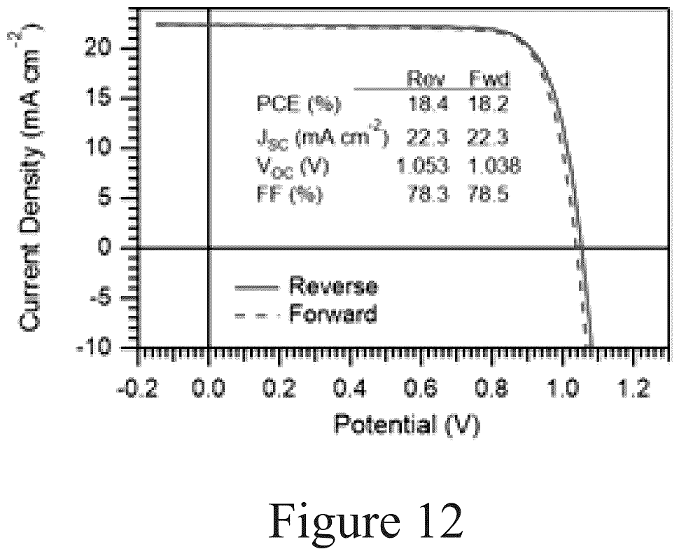

The KS8Br devices can have a band gap of 1.56-1.57 eV. The absorption spectrum of an example KS8Br film is shown in FIG. 11 with a JV response shown in FIG. 12.

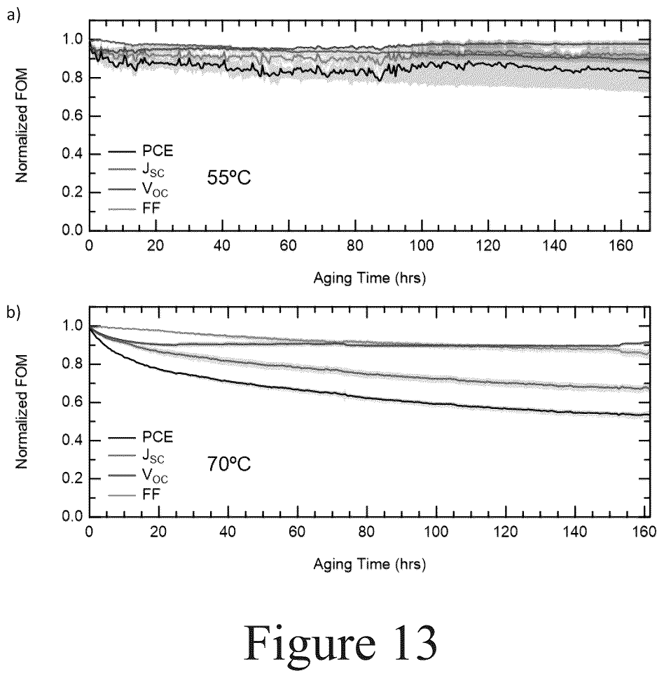

Stability of completed KS8Br devices has been evaluated in one of NREL's Stability Parameter Analyzer (SPA) systems (see FIG. 13). Devices were illuminated at 0.77 suns with a sulfur plasma lamp and kept at 55° C. in a N₂ atmosphere. Periodic JV sweeps were taken on each device. Devices were held under static load with a 510Ω resistor between sweeps.

### Materials and Methods

Materials: Lead iodide (PbI₂, 99.99%), lead bromide (PbBr2, >98.0%), bathocuproine (BCP, >99.0%), and methylammonium thiocyanate (MASCN, 97%) were purchased from Tokyo Chemical Industry Company, LTD (TCI). Cesium Iodide (CsI, 99.999% beads), poly(triaryl amine) (PTAA), dimethylformamide (DMF, 99.8%, anhydrous), dimethyl sulfoxide (DMSO, 99.9%, anhydrous), toluene (99.9%, anhydrous), 1-butyl-3-methylimidazolium tetrafluoroborate (BMIM:BF₄, 97%), 1-Butyl-3-methylimidazolium hexafluorophosphate (BMIM:PF6,97%), Y6 (99%), potassium thiocyanate (KSCN, 99%), lead thiocyanate (99.5%), Gallium(III) acetylacetonate (Ga(AcAc)₃, 99.99%), and phenylacetic acid (PA, 99%) were purchased from Sigma Aldrich. Y6 is also known BTP-4F or as: (2,2′-((2Z,2′Z)-((12,13-bis(2-ethylhexyl)-3,9-diundecyl-12,13-dihydro-[1,2,5]thiadiazolo [3,4-e]thieno [2″,3″: 4′,5′]thieno [2′,3′: 4,5]pyrrolo [3,2-g]thieno [2′,3′: 4,5]thieno [3,2-b]indole-2,10-diyl) bis (methanylylidene)) bis (5,6-difluoro-3-oxo-2,3-dihydro-1H-indene-2,1-diylidene)) dimalononitrile). Formamidinium iodide (FAI, 99.99%) and methylammonium bromide (MABr, 99.99%) were purchased from GreatCell Solar. C60 (C60, 99%) was purchased from Lumtec. ITO-coated (<20 Ω/sq) soda-lime glass substrates were purchased from Colorado Concept Coatings.

Spin Coated Device Fabrication: Substrates were cleaned by scrubbing with a detergent solution and then ultrasonication in DI water, acetone, and IPA. After a 15-minute ultraviolet ozone treatment on the bare substrates, the substrates were transferred into a nitrogen glovebox where the hole transport material and absorber layer were deposited. The HTL was formed by spin coating PTAA (2 mg/mL in toluene) at 6000 rpm for 30 seconds, then annealing at 100° C. for 10 minutes. The absorber layer was then deposited by distributing 30 μL of precursor ink onto the ITO substrate and spreading to cover the entire surface and spinning. The precursor was nitrogen quenched during spin coating using a ⅜″ inner diameter stainless steel tube positioned vertically 5 mm over the center of the substrate. Nitrogen pressure was approximately 100 psig with a flow of 3.2 SCFM. The spin recipe is outlined in Table 4 above. Following deposition of the perovskite, samples were annealed at 100° C. for 30 minutes in the glovebox. Devices were then transferred to an Angstrom evaporator for thermal deposition of C60 (25 nm)/BCP (6 nm)/Ag (100 nm). The device area is 0.112 cm² for each cell. Unless otherwise noted, the devices were measured with a metal aperture mask with an area of 0.059 cm² during the current-voltage measurements.

Evaporation: An Angstrom evaporator was used for thermal deposition of 25 nm of C60, 6 nm of BCP, and 100 nm of Ag. C60 was deposited at a rate of 0.2 Ås⁻¹ for the first 5 nm, then 0.5 Ås⁻¹ for the remaining 20 nm. BCP was evaporated at 0.1 Ås⁻¹ for all 6 nm. Ag was evaporated at 0.5 Ås⁻¹ for the first 10 nm and 2.0 Ås⁻¹ for the remaining 90 nm.

Sputtering: Substrates were UV-ozone treated immediately prior to nickel oxide deposition. Nickel oxide was deposited by RF sputtering in a Denton sputter coater from a 2.00″ diameter, 99.9% pure nickel oxide target. Sputtering is done at a pressure 25 mTorr of 1:1 Ar/ArO₂ at 60 W. Prior to deposition, the target is conditioned for 1000 seconds before sputtering for 400 seconds and depositing a NiO film with a thickness of 5 nm. Immediately prior to transferring substrates into the glovebox for deposition of following layers, the NiOₓ films were annealed in air at 300° C. for 10 minutes.

### Additives: High-Performing Concentrations/Methods:

BMIM:BF₄: Added 0.003-0.3 mol % of the ionic liquid directly to the precursor solution immediately before deposition.

BMIM:PF6: Added 0.003-0.3 mol % of the ionic liquid directly to the precursor solution immediately before deposition.

Pb(SCN)₂: 0.1-1 mol % of the salt was added to the precursor solution salts during the weighing process and solvated with the rest of the salts the day before use.

MASCN: 0.1-1 mol % of the salt was added to the precursor solution salts during the weighing process and solvated with the rest of the salts the day before use.

KSCN: 0.1-1 mol % of the salt was added to the precursor solution salts during the weighing process and solvated with the rest of the salts the day before use.

4F-PEAI: 0.5-1 mol % added to the precursor solution and applied by spin coating.

Excess PbI₂: 5 mol % excess PbI2 was added to the precursor solution and applied by spin coating.

### Post-Treatments:

Ga(AcAc)₃: Dissolved 0.25-1 mg Ga(AcAc)₃ in IPA, dynamically dispensed onto absorber layer at 6000 rpm and spun for 30 seconds.

PA: 0-1% PA was dissolved in X, dynamically dispensed onto absorber layer at 4000 rpm and spun for 30 seconds.

### Contact Engineering:

NiO: 5 nm deposited onto cleaned ITO and annealed before subsequent layers were deposited.

PTAA: Dissolved 0.1-2 mg in toluene and spun onto NiO.

Y6: Dissolved 2.5 mg in 1 mL chloroform and deposited onto the absorber layer at 6000 rpm and spun for 30 seconds.

### Device Testing:

Current-Voltage Characterization: Before and after the device aging, J-V measurements were taken in a N₂ glovebox. Illumination was provided with an AAA-class xenon arc lamp solar simulator calibrated to 1-sun intensity. A small fan was directed over the substrate to mitigate heating from illumination. J-V scans were taken with a Keithley 2450 source-measure unit. Sweeps were taken from −0.2 V to 1.2 V at a rate of 0.8 V/s. Cells were allowed to light-soak until a steady-state was reached as determined by successive reverse sweeps.

### Stability Characterization:

Solar cells without any encapsulation were loaded into a custom degradation testing setup, dubbed the Stability Parameter Analyzer (SPA). The setup consists of a flow chamber to control the environment of the cells, electrical housing and electronics, and a light source that provides constant illumination. The electronics switch between devices for characterization, measure J-V curves, and hold the devices under resistive load. In this study, devices were kept in a N₂ environment illuminated by sulfur plasma lamp at 0.7 suns. A substrate temperature of 55 or 70° C. was maintained with a closed water loop through the mounting block. Two test cells per substrate were held under a resistive load of 510Ω placing the cells near maximum power point while the remaining four were at an open-circuit light soak condition. Approximately every 30 minutes, the system removes the resistive load for the test cells and takes a JV scan using a Keithley 2450 source-measure unit. Figures of merit were calculated from the in-situ JV sweeps and used to evaluate performance.

TOF-SIMS Characterization: An ION-TOF TOF-SIMS V Time of Flight SIMS (TOF-SIMS) spectrometer was utilized for depth profiling and chemical imaging of the perovskite. Analysis was completed utilizing a 3-lens 30 keV BiMn primary ion gun. High mass resolution depth profiles were completed with a 30 KeV Bi₃⁺ primary ion beam, (0.8 pA pulsed beam current), a 50×50 μm area was analyzed with a 128:128 primary beam raster. 3-D tomography and high-resolution imaging was completed with a 30 KeV Bi₃⁺⁺ primary ion beam, (0.1 pA pulsed beam current), a 50×50 μm area was analyzed with a 512:512 primary beam raster. Sputter depth profiling was accomplished with 1 kV Cesium ion beam (6 nA sputter current) with a raster of 120×120 microns.

As described, a photovoltaic device can include a perovskite material. The perovskite material can have a controlled low amount of bromine relative to other halides. The perovskite material can include additives. The photovoltaic device can include a hole transport layer including nickel oxide. Hole transport layers can include a bilayer. Methods of making a photovoltaic device are provided. The methods include mixing selected precursors and additives. The additives can include ionic liquids. The methods can include a nitrogen treatment. The methods can include treating a perovskite layer with a surface modifier.

According to the embodiments provided herein, a photovoltaic device can comprise an absorber layer; and a first charge transport layer adjacent to the absorber layer. The first charge transport layer can be a hole transport layer (HTL). The absorber layer can comprise: a perovskite material having a composition: Cs_{(1-x-y)}MAₓFA_{y}Pb(I_{(1-z)}Br_{z})₃, wherein: 0<x<1, 0<y<1, (x+y)<1, and 0.06<z<0.10; and an additive.

In some embodiments, an additive can comprise at least one of: 1-butyl-3-methylimidazolium tetrafluoroborate (BMIM:BF₄), 1-butyl-3-methylimidazolium cation (BMIM⁺), tetrafluoroborate anion (BF₄⁻), tetradecyl dimethyl (3-sulfopropyl) ammonium hydroxide inner salt (TAH), choline chloride (CC), gallium acetylacetonate (Ga(AcAc)₃), lead(II) thiocyanate (Pb(SCN)₂), oleylamine (OAM), lead(II) chloride (PbCl₂), lead iodide (PbI₂), methylammonium thiocyanate (MASCN), potassium thiocyanate (KSCN) D-4-tert-butyl-Phe (D4TBP), phenethylammonium iodide (PEAI), 4-fluoro-phenylethylammonium iodide (4F-PEAI), 4-fluoro-phenylethylammonium iodide 4F-PEAI, Pb(SCN)₂, or thiocyanate (SCN⁻).

In some embodiments, an additive can comprise at least one of: BMIM:BF₄, TAH, CC, Ga(AcAc)₃, Pb(SCN)₂, OAM, PbCl₂, D4TBP, PEAI, or 4F-PEAI. In some embodiments, the additive comprises at least one of: BMIM:BF₄, Pb(SCN)₂, or PEAI.

In some embodiments, an additive can comprise at least two of: BMIM:BF₄, TAH, CC, Ga(AcAc)₃, Pb(SCN)₂, OAM, PbCl₂, D4TBP, PEAI, or 4F-PEAI. In some embodiments, the additive comprises BMIM:BF₄. In an embodiment, at least a portion of the BMIM:BF₄ is present in the absorber layer as 1-butyl-3-methylimidazolium cation (BMIM⁺) and tetrafluoroborate anion (BF₄⁻).

In an embodiment, the additive comprises Pb(SCN)₂. In an embodiment, at least a portion of the Pb(SCN)₂ is present in the absorber layer as thiocyanate (SCN⁻).

In an embodiment, the additive comprises PEAI.

In an embodiment, the additive comprises at least two of: BMIM:BF₄, TAH, CC, Ga(AcAc)₃, Pb(SCN)₂, OAM, PbCl₂, D4TBP, PEAI, or 4F-PEAI.

In some embodiments, first charge transport layer is a hole transport layer (HTL) and the HTL comprises nickel oxide.

In some embodiments, the perovskite material composition is: Cs_{(1-x-y)}MAₓFA_{y}Pb(I_{(1-z)}Br_{z})₃, wherein 0.02≤x≤0.08, 0.82≤y≤0.92, and 0.07≤z≤0.09. The additive can comprise at least one of: BMIMBF₄, Pb(SCN)₂, or PEAI. The first charge transport layer can comprise a first sublayer and a second sublayer. The first sublayer can comprise an inorganic hole transport material. The second sublayer can comprise an organic hole transport material. The second sublayer can be positioned between the absorber layer and the first sublayer; and the second sublayer can be adjacent to and in direct contact with both the absorber layer and the first sublayer.

In some embodiments, the first sublayer has a thickness in a range from 1.5 nm to 100.0 nm, and the second sublayer has a thickness in a range from 0.2 nm to 15.0 nm.

In some embodiments, the first contact layer comprises nickel oxide. In some embodiments, the first sublayer comprises nickel oxide, and the second sublayer comprises PTAA.

In some embodiments, the additive is present in the absorber layer with a concentration gradient.

In an embodiment, a concentration of the additive can be higher in a HTL-adjacent region of the absorber layer than in a central region of the absorber layer, wherein the central region corresponds to a middle 70% of a thickness of the absorber layer, and the HTL-adjacent region corresponds to 15% of the thickness of the absorber layer nearest the first charge transport layer. In an embodiment, the concentration of the additive in the HTL-adjacent region is at least two times greater than in the central region.

In some embodiments, the absorber layer is formed over a p-type first charge transport layer, and an n-type charge transport layer is formed over the absorber layer to produce a p-i-n structure. The p-type first charge transport layer can be a hole transport layer (HTL) and the n-type charge transport layer can be an electron transport layer (ETL).

In an embodiment, a concentration of the additive can be higher in an ETL-adjacent region of the absorber layer than in a central region of the absorber layer, wherein the central region corresponds to a middle 70% of a thickness of the absorber layer, and the ETL-adjacent region corresponds to 15% of the thickness of the absorber layer nearest the second charge transport layer. In an embodiment, the concentration of the additive in the ETL-adjacent region is at least two times greater than in the central region. In some embodiments, having the concentration of the additive higher in an ETL-adjacent region of the absorber layer, the additive comprises PEAI.

In an embodiment, the photovoltaic device comprises a second contact layer, wherein the second charge transport layer is disposed between the between the second contact layer and the absorber layer.

According to the embodiments provided herein, a photovoltaic device can comprise an absorber layer and the absorber layer can comprise a triple cation perovskite material forming a polycrystalline thin film. In an embodiment, the absorber layer comprises a triple cation perovskite material, wherein the perovskite material composition is approximately equal to Cs_{0.05}MA_{0.08}FA_{0.87}Pb(I_{0.92}Br_{0.08})₃.

In an embodiment, the photovoltaic device comprises a first contact layer, wherein the first charge transport layer is disposed between the between the first contact layer and the absorber layer. In an embodiment, the photovoltaic device comprises a second contact layer, wherein the second charge transport layer is disposed between the between the second contact layer and the absorber layer.

According to the embodiments provided herein, a method for forming a perovskite photovoltaic device may include applying a solution to a surface of a layer resulting in a liquid layer of the solution positioned on the surface; and treating the liquid layer resulting in the forming of a solid perovskite layer, wherein, the solution comprises a perovskite precursor, an additive, and a solvent, and the treating removes at least a portion of the solvent. In some embodiments, the treating is performed by directing nitrogen to the liquid layer.

According to the embodiments provided herein, a method for forming a perovskite photovoltaic device may include: providing a substrate stack, the substrate stack having a p-type contact layer; forming a first hole transport sublayer over the transparent contact layer; forming a second hole transport sublayer over the first hole transport sublayer; and forming a perovskite absorber layer adjacent to the second hole transport sublayer. In some embodiments, the method further comprises forming an electron transport layer (ETL) over the perovskite absorber layer and forming an n-type contact layer over the ETL.

In some embodiments, the step of depositing a layer, or layer precursor solution, comprises at least one of: spin coating, slot coating, spray coating, blade coating, or dip coating.

According to the embodiments provided herein, a method for forming a perovskite photovoltaic device can include: providing a first contact layer on a substrate; depositing a first charge transport layer over the first contact layer; applying a precursor solution to a surface of a first charge transport layer resulting in a liquid layer of the precursor solution on the surface of the first charge transport layer, wherein: the precursor solution comprises a perovskite precursor, an additive, and a solvent; and treating the liquid layer to remove at least a portion of the solvent, thereby forming an absorber layer comprising a solid perovskite material. In some embodiments, the additive is provided as an ionic liquid. In some embodiments, forming the absorber layer comprises mixing a precursor solution comprising: MABr, CsI, PbBr₂, FAI, and PbI₂, thereby forming triple cation perovskite. In some embodiments, treating the liquid layer comprises directing nitrogen gas to contact a surface of the liquid layer.

In some embodiments, the solid perovskite layer has a halide atomic percent in a range of 6.0% to 9.0% bromine. In some embodiments, the absorber layer has a halide atomic percent in a range of 6.0% to 9.0% bromine. In some embodiments, the absorber layer has a halide atomic percent in a range of 7.0% to 8.5% bromine.

In some embodiments, the method comprises treating the absorber layer with a surface modifier and subsequently providing a second contact layer over the absorber layer. In some embodiments, the method includes treating the solid perovskite material with a surface modifier, prior to providing the second contact layer. In some embodiments, the surface modifier comprises at least one of Ga(AcAc)₃ or PA.

In some embodiments, depositing the first charge transport layer comprises depositing at least one hole transport material. In some embodiments, the first charge transport layer is a bilayer comprising a first sublayer and a second sublayer. In some embodiments, the first sublayer comprises nickel oxide. In some embodiments, the second sublayer comprises PTAA. In some embodiments, depositing the first charge transport layer comprises: forming a layer of nickel oxide over the first contact and forming a layer of PTAA over the layer of nickel oxide. In some embodiments, depositing the first charge transport layer comprises: forming a layer of nickel oxide and forming a layer of PTAA.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A photovoltaic device comprising:
an absorber layer; and
a first charge transport layer adjacent to the absorber layer, wherein:
the absorber layer comprises:
a perovskite material having a composition: Cs_{(1-x-y)}MAₓFA_{y}Pb(I_{(1-z)}Br_{z})₃, wherein: 0<x<1, 0<y<1, (x+y)<1, and 0.06<z<0.10; and
an additive comprising at least one of: 1-butyl-3-methylimidazolium tetrafluoroborate (BMIM:BF₄), tetradecyl dimethyl (3-sulfopropyl) ammonium hydroxide inner salt (TAH), choline chloride (CC), gallium acetylacetonate (Ga(AcAc)₃), lead(II) thiocyanate (Pb(SCN)₂), oleylamine (OAM), lead(II) chloride (PbCl₂), D-4-tert-butyl-Phe (D4TBP), phenethylammonium iodide (PEAI), or 4-fluoro-phenylethylammonium iodide (4F-PEAI); and
the first charge transport layer is a hole transport layer (HTL).

2. The photovoltaic device of claim 1, wherein:
the perovskite material composition is: Cs_{(1-x-y)}MAₓFA_{y}Pb(I_{(1-z)}Br_{z})₃, wherein 0.02≤x≤0.08, 0.82≤y≤0.92, and 0.07≤z≤0.09;
the additive comprises at least one of: BMIM:BF₄, Pb(SCN)₂, or 4F-PEAI; and
the first charge transport layer comprises a first sublayer and a second sublayer, wherein:
the first sublayer comprises an inorganic hole transport material;
the second sublayer comprises an organic hole transport material;
the second sublayer is positioned between the absorber layer and the first sublayer; and
the second sublayer is adjacent to and in direct contact with both the absorber layer and the first sublayer.

3. The photovoltaic device of claim 2, wherein:
the first sublayer comprises nickel oxide;
the first sublayer has a thickness in a range from 1.5 nm to 100.0 nm;
the second sublayer comprises PTAA; and
the second sublayer has a thickness in a range from 0.2 nm to 15.0 nm.

4. The photovoltaic device of claim 1, wherein the additive is present in the absorber layer with a concentration gradient.

5. The photovoltaic device of claim 1, wherein the additive comprises BMIM:BF₄.

6. The photovoltaic device of claim 5, wherein at least a portion of the BMIM:BF₄ is present in the absorber layer as at least one of 1-butyl-3-methylimidazolium cation (BMIM⁺) or tetrafluoroborate anion (BF₄⁻).

7. The photovoltaic device of claim 1, wherein the additive comprises Pb(SCN)₂.

8. The photovoltaic device of claim 7, wherein at least a portion of the Pb(SCN)₂ is present in the absorber layer as at least one of thiocyanate (SCN⁻) or Pb²⁺.

9. The photovoltaic device of claim 1, wherein the additive comprises PEAI.

10. The photovoltaic device of claim 1, wherein the additive comprises at least two of: BMIM:BF₄, TAH, CC, Ga(AcAc)₃, Pb(SCN)₂, OAM, PbCl₂, D4TBP, PEAI, or 4F-PEAI.

11. The photovoltaic device of claim 1, wherein the perovskite material composition is approximately equal to Cs_{0.05}MA_{0.08}FA_{0.87}Pb(I_{0.92}Br_{0.08})₃.

12. A method of making a photovoltaic device comprising:
depositing a first charge transport layer over a first contact layer;
applying a precursor solution to a surface of a first charge transport layer resulting in a liquid layer of the precursor solution on the surface of the first charge transport layer, wherein:
the precursor solution comprises a perovskite precursor, an additive, and a solvent;
treating the liquid layer to remove at least a portion of the solvent, thereby forming an absorber layer comprising a solid perovskite material.

13. The method of claim 12, wherein the step of treating the liquid layer comprises directing nitrogen gas to contact a surface of the liquid layer.

14. The method of claim 12, wherein:
the perovskite precursor in the precursor solution comprises: MABr, CsI, PbBr₂, FAI, and PbI₂; and
the solid perovskite layer has a halide atomic percent in a range of 6.0% to 9.0% bromine.

15. The method of claim 12, further comprising:
providing a second contact layer over the absorber layer; and
treating the absorber layer with a surface modifier, after the step of forming an absorber layer comprising the solid perovskite material, and prior to providing the second contact layer;
wherein the surface modifier comprises at least one of Ga(AcAc)₃ or PA.

16. The method of claim 12, wherein the additive comprises the additive comprises at least one of: BMIM:BF₄, Pb(SCN)₂, or 4F-PEAI.

17. The method of claim 12, wherein the first charge transport layer is a bilayer comprising a first sublayer and a second sublayer, wherein the second sublayer is adjacent to and in direct contact with both the absorber layer and the first sublayer.

18. The method of claim 12, wherein:
the first charge transport layer is a bilayer comprising a first sublayer and a second sublayer;
the first sublayer comprises nickel oxide;
the second sublayer comprises PTAA; and
depositing the first charge transport layer comprises: forming a layer of nickel oxide over the first contact and forming a layer of PTAA over the layer of nickel oxide.
